(19) United States
(12) Patent Application Publication
(10) Pub. No.: US 2025/0031420 A1
(43) Pub. Date: Jan. 23, 2025

(54) SEMICONDUCTOR DEVICE INCLUDING MEMORY ELEMENT AND METHOD FOR MANUFACTURING THE SAME

(71) Applicant: Unisantis Electronics Singapore Pte. Ltd., Singapore (SG)

(72) Inventors: Nozomu HARADA, Tokyo (JP); Masakazu KAKUMU, Tokyo (JP); Koji SAKUI, Tokyo (JP)

(21) Appl. No.: 18/424,133

(22) Filed: Jan. 26, 2024

(30) Foreign Application Priority Data
Jul. 21, 2023 (WO) PCT/JP2023/026771

(51) Int. Cl. H01L 29/06; H01L 29/423; H01L 29/66; H01L 29/786; H10B 43/27

(52) U.S. Cl. CPC H01L 29/0692; H01L 29/42372; H01L 29/66666; H01L 29/7869; H10B 43/27

(57) ABSTRACT

In a semiconductor device including a memory element, a first mask material layer formed in a self-aligned manner and second mask material layers formed on both sides of the first mask material layer are used to form a second gate insulating layer and a second gate conductor layer 35 at the area of the first mask material layer and N layers and N⁺ layers at the areas of the second mask material layers, and a P-layer semiconductor pillar, a first gate insulating layer, a first gate conductor layer, a second gate insulating layer, a second gate conductor layer, N layers, and N⁺ layers, which are all elements constituting a memory cell, are formed in a self-aligned manner.

### CROSS-REFERENCE TO RELATED APPLICATIONS

This application claims priority to PCT/JP2023/026771, filed Jul. 21, 2023, the entire content of which is incorporated herein by reference.

### BACKGROUND OF THE INVENTION

### 1. Field of the Invention

The present invention relates to a semiconductor device including a memory element and a method for manufacturing the semiconductor device.

### 2. Description of the Related Art

In recent large scale integration (LSI) technology development, there has been a need for a semiconductor device including a memory element with a higher degree of integration, higher performance, lower power consumption, and more functions.

Surrounding gate transistors (SGTs) allows semiconductor devices to have higher densities than planar metal-oxide-semiconductor (MOS) transistors. Using such SGTs as selection transistors can achieve increases in the degree of integration of devices such as a dynamic random access memory (DRAM) to which a capacitor is connected (see, for example, H. Chung, H. Kim, H. Kim, K. Kim, S. Kim, K. W. Song, J. Kim, Y. C. Oh, Y. Hwang, H. Hong, G. Jin, and C. Chung: “4F2 DRAM Cell with Vertical Pillar Transistor (VPT)”, 2011 Proceeding of the European Solid-State Device Research Conference, (2011)), a phase change memory (PCM) to which a variable resistance element is connected (see, for example, H. S. Philip Wong, S. Raoux, S. Kim, Jiale Liang, J. R. Reifenberg, B. Rajendran, M. Asheghi, and K. E. Goodson: “Phase Change Memory”, Proceeding of IEEE, Vol. 98, No. 12, December, pp2b012b27 (2010)), a resistive random access memory (RRAM) (see, for example, K. Tsunoda, K. Kinoshita, H. Noshiro, Y. Yamazaki, T. Iizuka, Y. Ito, A. Takahashi, A. Okano, Y. Sato, T. Fukano, M. Aoki, and Y. Sugiyama: “Low Power and High Speed Switching of Ti-doped NiO ReRAM under the Unipolar Voltage Source of less than 3 V”, IEDM (2007)), and a magneto-resistive random access memory (MRAM) which varies its resistance by varying the direction of magnetic spin using an electric current (see, for example, W. Kang, L. Zhang, J. Klein, Y. Zhang, D. Ravelosona, and W. Zhao: “Reconfigurable Codesign of STT-MRAM Under Process Variations in Deeply Scaled Technology”, IEEE Transaction on Electron Devices, pp. 1-9 (2015)). There are also, for example, a capacitor-less DRAM memory cell constituted by a single MOS transistor (see M. G. Ertosun, K. Lim, C. Park, J. Oh, P. Kirsch, and K. C. Saraswat: “Novel Capacitorless Single-Transistor Charge-Trap DRAM (1T CT DRAM) Utilizing Electron”, IEEE Electron Device Letter, Vol. 31, No. 5, pp. 405-407 (2010)) and a DRAM memory cell having two groove portions for storing carriers and two gate electrodes (see Md. Hasan Raza Ansari, Nupur Navlakha, Jae Yoon Lee, Seongjae Cho, “Double-Gate Junctionless 1T DRAM With Physical Barriers for Retention Improvement”, IEEE Trans, on Electron Devices vol. 67, pp. 1471-1479 (2020)). However, a capacitor-less DRAM has a problem in that it is greatly affected by coupling of a floating body with a gate electrode from a word line, so that a sufficient voltage margin cannot be provided. As an alternative to this, there is a memory element that has a second channel connecting to a first channel of a MOS transistor, the second channel being surrounded by gate insulating layers and gate conductor layers, and has an impurity region on the side of the second channel facing away from the first channel (US2023/0077140/A1).

The operation of a memory cell disclosed in US2023/0077140/A1 will be described with reference to FIGS. 5A to 5CC. FIG. 5A illustrates a vertical sectional structure of the memory cell. An N layer 102 containing a donor impurity is disposed on a Player 101 (hereinafter, a semiconductor region containing a donor impurity is referred to as an “N layer”). A pillar-shaped P layer 103a containing an acceptor impurity is disposed on the N layer 102. A P layer 103b is disposed on the P layer 103a. A first gate insulating layer 105 is disposed in contact with a pillar-shaped side surface of the P layer 103a. A first gate conductor layer 106 is disposed in contact with an outer side surface of the first gate insulating layer 105. A first insulating layer 104 is disposed between the N layer 102 and the gate conductor layer 106. A second insulating layer 108 is disposed on the first gate insulating layer 105 and the first gate conductor layer 106. An N⁺ layer 111a and an N⁺ layer 111b containing a highly concentrated donor impurity are disposed on both sides of the P layer 103b in a line X-X′ direction. A second gate insulating layer 109 is disposed in contact with an upper portion of the P layer 103b between the N⁺ layer 111a and the N⁺ layer 111b. A second gate conductor layer 110 is disposed in contact with an upper portion of the second gate insulating layer 109.

The N⁺ layer 111a is connected to a source line SL, the N⁺ layer 111b is connected to a bit line BL, the gate conductor layer 110 is connected to a word line WL, the gate conductor layer 106 is connected to a plate line PL, and the N layer 102 is connected to a control line CDC. The memory is operated by controlling the electric potentials of the source line SL, the bit line BL, the plate line PL, and the word line WL. In an actual memory device, a large number of the above-described memory cells are arranged on the P layer 101 in a two-dimensional array.

A write operation of the memory cell will be described with reference to FIGS. 5BA, 5BB, and 5BC. In FIG. 5BA, a voltage of 0 V is applied to the P layer 101, a voltage of 0 V is input to the N⁺ layer 111a, a voltage of 3 V is input to the N⁺ layer 111b, a voltage of 0 V is input to the first gate conductor layer 106, and a voltage of 1.5 V is input to the second gate conductor layer 110 connected to the word line WL. In the P layer 103b immediately below the gate insulating layer 109 underlying the gate conductor layer 110, an inversion layer 112 is partly formed and a pinch-off point 113 is present. In this case, the MOS transistor including the second gate conductor layer 110 operates in a saturation region.

As a result, the electric field is maximized between the pinch-off point 113 and the N⁺ layer 111b, and an impact ionization phenomenon occurs in this region. As a result of this impact ionization phenomenon, electrons accelerated from the N⁺ layer 111a toward the N⁺ layer 111b collide with the Si lattice, and the kinetic energy generates electron-hole pairs. Holes 114a generated diffuse, due to the concentration gradient, toward regions with lower hole concentrations. Electrons are removed from the N⁺ layer 111b. The group of holes 114a may be generated by applying a gate-induced drain-leakage (GIDL) current instead of causing the above impact ionization phenomenon (see, for example, E. Yoshida, T, Tanaka, “A Capacitorless 1T-DARM Technology Using Gate-Induced Drain-Leakage (GIDL) Current for Low-Power and High-Speed Embedded Memory”, IEEE Trans, on Electron Devices vol. 53, pp. 692-697 (2006)).

As illustrated in FIG. 5BB, the word line WL, the bit line BL, the plate line PL, and the source line SL are set to, for example, 0 V immediately after writing to accumulate the group of holes 114b in the P layer 103a. As a result of this, the hole concentration of the P layer 103a becomes higher than the hole concentration of the P layer 103b. Since the P layer 103a and the P layer 103b are electrically connected to each other, the P layer 103a practically serving as a substrate of the MOS transistor including the gate conductor layer 110 is charged to a positive bias. The threshold voltage of the MOS transistor including the second gate conductor layer 110 is lowered by the positive substrate bias effect of the group of holes 114b accumulated in the P layer 103a. Thus, as illustrated in FIG. 5BC, the threshold voltage of the MOS transistor including the second gate conductor layer 110 connected to the word line WL is lowered.

Next, an erase operation mechanism will be described with reference to FIGS. 5CA, 5CB, and 5CC. As illustrated in FIG. 5CA, before an erase operation, the group of holes 114b generated by impact ionization and accumulated are stored mainly in the Player 103a. At the time of the erase operation, for example, the voltage of the source line SL is set to −0.5 V, and the voltage of the plate line PL is set to 2 V. As a result, irrespective of the value of the initial potential of the P layer 103a, the PN junction between the N⁺ layer 111a and the P layer 103b is forward biased. As a result, as illustrated in FIG. 5CB, the group of holes 114b generated by impact ionization in the previous cycle and stored mainly in the P layer 103a move to the N⁺ layer 111a connected to the source line. Furthermore, as a result of applying a voltage of 2 V to the plate line PL, an inversion layer 116 is formed at the interface between the first gate insulating layer 105 and the P layer 103a and comes into contact with the N layer 102. Therefore, the holes 114b accumulated in the P layer 103a flow from the P layer 103a to the N layer 102 and the inversion layer 116 to recombine with electrons. As a result, the hole concentration of the P layer 103a decreases with time, and the threshold voltage of the MOSFET becomes higher than that at the time of writing of “1” and returns to the initial state. Thus, as illustrated in FIG. 5CC, the MOSFET including the gate conductor layer 110 connected to the word line WL returns to the initial threshold. This erased state of the memory corresponds to logic storage data “0”.

The memory cell illustrated in FIGS. 5A to 5CC is required to achieve, in the formation of the N layer 102, the P layers 103a and 103b, the first gate insulating layer 105, the first gate conductor layer 106, the second gate insulating layer 109, the first gate conductor layer 110, and the N⁺ layers 111a and 111b, which are constituents, a higher accuracy, a higher density, and a simpler process which leads to a lower cost.

### SUMMARY OF THE INVENTION

In a memory device, it is necessary to manufacture memory cells densely and inexpensively.

To achieve this, a method for manufacturing a semiconductor device including a memory element according to a first invention includes:
a step of forming, on a semiconductor layer, a first band-shaped material layer extending in a first direction in plan view;
a step of forming, on both sides of the first band-shaped material layer, a second band-shaped material layer having an equal width;
a step of forming, on the semiconductor layer, a third band-shaped material layer covering the first and second band-shaped material layers and extending in a second direction perpendicular to the first direction;
a step of etching the first and second band-shaped material layers using the third band-shaped material layer as a mask to form a first mask material layer that is a part of the first band-shaped material layer and, on both sides of the first mask material layer, a second mask material layer that is a part of the second band-shaped material layer;
a step of etching the semiconductor layer using the first and second mask material layers as masks to form a semiconductor pillar;
a step of forming, in a bottom portion of the semiconductor pillar, a first impurity region having a conductivity type opposite to that of the semiconductor pillar;
a step of forming a first gate insulating layer in contact with a side surface of the semiconductor pillar;
a step of forming one or two first gate conductor layers in contact with a side surface of the first gate insulating layer;
a step of removing the second mask material layer;
a step of forming, in top portions of the semiconductor pillar on both sides of an area where the first mask material layer is disposed in plan view, a second impurity region and a third impurity region having the same conductivity type as that of the first impurity region;
a step of removing the first mask material layer to form a first hole; and
a step of forming a second gate insulating layer in contact with an inner side surface of the first hole and a second gate conductor layer in contact with the second gate insulating layer.

According to a second invention, the first invention includes:
a step of removing the second mask material layer while leaving the first mask material layer;
a step of forming a first low-concentration impurity region in top portions of the semiconductor pillar on the both sides of the first mask material layer in plan view;
a step of forming, on the semiconductor pillar, a third mask material layer having an equal width on side surfaces of the first mask material layer in the second direction; and
a step of forming, in top portions of the semiconductor pillar on both sides of the third mask material layer, a first high-concentration impurity region containing more impurities than the first low-concentration impurity region,
wherein the first low-concentration impurity region and the first high-concentration impurity region form the second impurity region and the third impurity region.

According to a third invention, in the first invention, after the second impurity region and the third impurity region are formed using the first mask material layer as a mask, the first mask material layer is removed, and then the second gate insulating layer and the second gate conductor layer are formed.

According to a fourth invention, in the first invention,
after the first mask material layer is removed and the second gate insulating layer and the second gate conductor layer are formed on the inner side surface of the first hole, the second mask material layer is removed, and then the second impurity region and the third impurity region are formed.

According to a fifth invention, the first invention further includes:
a step of forming the second mask material layer as a fourth mask material layer formed on the both sides of the first mask material layer and having an equal width and a fifth mask material layer formed on both sides of the fourth mask material layer and having an equal width;
a step of removing the fifth mask material layer;
a step of forming a second high-concentration impurity region in top portions of the semiconductor pillar at areas where the fifth mask material layer has once been present in plan view;
a step of removing the fourth mask material layer; and
a step of forming a second low-concentration impurity region in top portions of the semiconductor pillar at areas where the fourth mask material layer has once been present in plan view.

According to a sixth invention, the first invention further includes
a step of forming the second impurity region and the third impurity region on both sides of the first mask material layer such that the second impurity region and the third impurity region are adjacent to the first mask material layer and include an upper surface portion of the semiconductor pillar in plan view.

According to a seventh invention, the first invention further includes:
a step of removing the first mask material layer;
a step of forming a second hole by etching a top portion of the semiconductor pillar at an area of the removed first mask material layer using the second mask material layer as an etching mask such that a bottom of the hole in a vertical direction is located higher than an upper surface of the first gate conductor layer;
a step of forming the second gate insulating layer and the second gate conductor layer in contact with an inner side surface of the second hole;
a step of removing the second mask material layer; and
a step of forming the second impurity region and the third impurity region in top portions of the semiconductor pillar located above a bottom portion of the second hole.

According to an eighth invention, in the seventh invention, after the second gate insulating layer and the second gate conductor layer are formed, the second mask material layer is removed, and then the second impurity region and the third impurity region are formed.

According to a ninth invention, in the seventh invention, after the second impurity region and the third impurity region are formed using the first mask material layer as a mask, the second gate insulating layer and the second gate conductor layer are formed in contact with the inner side surface of the second hole formed by removing the first mask material layer.

According to a tenth invention, in the seventh invention, in the vertical direction, an upper surface of the second gate conductor layer is located near bottom portions of the second impurity region and the third impurity region.

According to an eleventh invention, the first invention includes:
a step of removing the second mask material layer while leaving the first mask material layer;
a step of forming a second low-concentration impurity region in top portions of the semiconductor pillar at areas of the second mask material layer in plan view; and
a step of forming a second high-concentration impurity region in contact with an outer side of the second low-concentration impurity region in the second direction.

According to a twelfth invention, in the eleventh invention, the second high-concentration impurity region is formed by selective epitaxial crystal growth.

According to a thirteenth invention, in the eleventh invention, the second high-concentration impurity region is connected to an adjacent high-concentration impurity region of an adjacent memory cell.

According to a fourteenth invention, the first invention further includes:
a step of forming, after forming the semiconductor pillar, an impurity layer having a conductivity type opposite to that of the semiconductor pillar in an upper layer of the semiconductor layer at an outer peripheral portion of the semiconductor pillar; and
a step of thermally oxidizing the upper layer of the semiconductor layer at the outer peripheral portion of the semiconductor pillar to form a thermally oxidized layer in the outer peripheral portion and an inner peripheral portion of the semiconductor pillar,
wherein the impurity layer having the opposite conductivity type spreads, upon heat treatment, throughout the bottom portion of the semiconductor pillar to form the first impurity region.

According to a fifteenth invention, the first invention includes
a step of dividing the first gate conductor layer at a central portion between the second impurity region and the third impurity region in a direction in which the second impurity region and the third impurity region connect to each other in plan view to form a fourth gate conductor layer and a fifth gate conductor layer.

A sixteenth invention includes:
a semiconductor pillar extending in a vertical direction on a substrate;
a first impurity region connecting to a bottom portion of the semiconductor pillar;
a first gate insulating layer in contact with a lower side surface of the semiconductor pillar;
one or two first gate conductor layers in contact with a side surface of the first gate insulating layer;
a second impurity region and a third impurity region that are disposed above an upper surface of the first gate conductor layer in the vertical direction and disposed at both ends of a top portion of the semiconductor pillar in a first direction in plan view;
a second gate insulating layer disposed on the top portion of the semiconductor pillar between the second impurity region and the third impurity region; and
a second gate conductor layer in contact with the second gate insulating layer,
wherein a portion of the semiconductor pillar that is in contact with the first gate insulating layer and a portion of the semiconductor pillar that includes the second impurity region and the third impurity region overlap each other with a substantially equal shape in plan view.

According to a seventeenth invention, in the sixteenth invention, the second impurity region includes a first low-concentration impurity region disposed outside the second gate conductor layer in plan view and having a low impurity concentration and a first high-concentration impurity region disposed outside the first low-concentration impurity region in plan view, and
the third impurity region includes a second low-concentration impurity region disposed outside the second gate conductor layer in plan view and equal in width and impurity concentration to the first low-concentration impurity region and a second high-concentration impurity region disposed outside the second low-concentration impurity region in plan view and equal in width and impurity concentration to the first high-concentration impurity region.

According to an eighteenth invention, in the sixteenth invention, the second impurity region includes a third low-concentration impurity region having a low impurity concentration, the third impurity region includes a fourth low-concentration impurity region having an impurity concentration equal to that of the third low-concentration impurity region, and in the first direction, a third high-concentration impurity region is disposed in contact with an outer side of the third low-concentration impurity region, and a fourth high-concentration impurity region having an impurity concentration equal to that of the third high-concentration impurity region is disposed in contact with an outer side of the fourth low-concentration impurity region.

According to a nineteenth invention, in the eighteenth invention, the third and fourth high-concentration impurity regions are formed by selective epitaxial crystal growth.

According to a twentieth invention, in the sixteenth invention, the two separate first gate conductor layers are configured such that a fixed voltage or zero voltage is applied to one of the two separate first gate conductor layers.

According to a twenty-first invention, in the twentieth invention, one of the two separate first gate conductor layers to which a fixed voltage or zero voltage is applied is adjacent to the second impurity region connected to a bit line or the third impurity region in plan view.

According to a twenty-second invention, in the sixteenth invention, an upper surface of the semiconductor pillar between the second impurity region and the third impurity region is located below bottom portions of the second impurity region and the third impurity region.

According to a twenty-third invention, in the twenty-second invention, a wiring metal layer is disposed in contact with an upper portion of the second gate conductor layer, and an upper end of the wiring metal layer is located below or near lower ends of the second and third impurity regions in the vertical direction.

According to a twenty-fourth invention, in the seventeenth invention, a wiring metal layer is disposed in contact with an upper portion of the second gate conductor layer, and an upper end of the wiring metal layer is located below or near lower ends of the second and third impurity regions in the vertical direction.

According to a twenty-fifth invention, in the sixteenth invention, the first low-concentration impurity region surrounds an entire side surface of the first high-concentration impurity region, and the second low-concentration impurity region surrounds an entire side surface of the second high-concentration impurity region.

According to a twenty-sixth invention, in the sixteenth invention, a thermally oxidized layer is disposed between the substrate and the first gate conductor layer and disposed in an outer peripheral portion and an inner peripheral portion of the bottom portion of the semiconductor pillar.

According to a twenty-seventh invention, in the sixteenth invention, the second impurity region and the third impurity region are disposed so as to be adjacent to the second gate conductor layer and to include an upper surface portion of the semiconductor pillar in plan view.

### BRIEF DESCRIPTION OF THE DRAWINGS

FIGS. 1AA, 1AB and 1AC are diagrams for explaining a method for manufacturing a memory device according to a first embodiment;

FIGS. 1BA, 1BB and 1BC are diagrams for explaining the method for manufacturing a memory device according to the first embodiment;

FIGS. 1CA, 1CB and 1CC are diagrams for explaining the method for manufacturing a memory device according to the first embodiment;

FIGS. 1DA, 1DB and 1DC are diagrams for explaining the method for manufacturing a memory device according to the first embodiment;

FIGS. 1EA, 1EB and 1EC are diagrams for explaining the method for manufacturing a memory device according to the first embodiment;

FIGS. 1FA, 1FB and 1FC are diagrams for explaining the method for manufacturing a memory device according to the first embodiment;

FIGS. 1GA, 1GB and 1GC are diagrams for explaining the method for manufacturing a memory device according to the first embodiment;

FIGS. 1HA, 1HB and 1HC are diagrams for explaining the method for manufacturing a memory device according to the first embodiment;

FIGS. 1IA, 1IB and 1IC are diagrams for explaining the method for manufacturing a memory device according to the first embodiment;

FIGS. 1JA, 1JB and 1JC are diagrams for explaining the method for manufacturing a memory device according to the first embodiment;

FIGS. 1KA, 1KB and 1KC are diagrams for explaining the method for manufacturing a memory device according to the first embodiment;

FIGS. 1LA, 1LB and 1LC are diagrams for explaining the method for manufacturing a memory device according to the first embodiment;

FIGS. 1MA, 1MB and 1MC are diagrams for explaining the method for manufacturing a memory device according to the first embodiment;

FIGS. 2AA, 2AB and 2AC are diagrams for explaining a method for manufacturing a memory device according to a second embodiment;

FIGS. 2BA, 2BB and 2BC are diagrams for explaining the method for manufacturing a memory device according to the second embodiment;

FIGS. 2CA, 2CB and 2CC are diagrams for explaining the method for manufacturing a memory device according to the second embodiment;

FIGS. 2DA, 2DB and 2DC are diagrams for explaining the method for manufacturing a memory device according to the second embodiment;

FIGS. 3AA, 3AB and 3AC are diagrams for explaining a method for manufacturing a memory device according to a third embodiment;

FIGS. 3BA, 3BB and 3BC are diagrams for explaining the method for manufacturing a memory device according to the third embodiment;

FIGS. 3CA, 3CB and 3CC are diagrams for explaining the method for manufacturing a memory device according to the third embodiment;

FIGS. 3DA, 3DB and 3DC are diagrams for explaining the method for manufacturing a memory device according to the third embodiment;

FIGS. 3EA, 3EB and 3EC are diagrams for explaining the method for manufacturing a memory device according to the third embodiment;

FIGS. 3FA, 3FB and 3FC are diagrams for explaining the method for manufacturing a memory device according to the third embodiment;

FIGS. 3GA, 3GB and 3GC are diagrams for explaining the method for manufacturing a memory device according to the third embodiment;

FIGS. 3HA, 3HB and 3HC are diagrams for explaining the method for manufacturing a memory device according to the third embodiment;

FIGS. 4AA, 4AB and 4AC are diagrams for explaining a method for manufacturing a memory device according to a fourth embodiment;

FIGS. 4BA, 4BB and 4BC are diagrams for explaining the method for manufacturing a memory device according to the fourth embodiment;

FIGS. 4CA, 4CB and 4CC are diagrams for explaining the method for manufacturing a memory device according to the fourth embodiment;

FIGS. 4DA, 4DB and 4DC are diagrams for explaining the method for manufacturing a memory device according to the fourth embodiment;

FIGS. 4EA, 4EB and 4EC are diagrams for explaining the method for manufacturing a memory device according to the fourth embodiment;

FIGS. 4FA, 4FB and 4FC are diagrams for explaining the method for manufacturing a memory device according to the fourth embodiment;

FIG. 5A illustrates a vertical sectional structure of a memory cell of the related art;

FIGS. 5BA, 5BB and 5BC illustrate a write operation of the memory cell of the related art; and

FIGS. 5CA, 5CB and 5CC illustrate an erase operation mechanism of the memory cell of the related art.

### DESCRIPTION OF THE PREFERRED EMBODIMENTS

Hereinafter, methods for manufacturing a semiconductor device including a memory element according to embodiments of the present invention will be described with reference to the drawings.

### First Embodiment

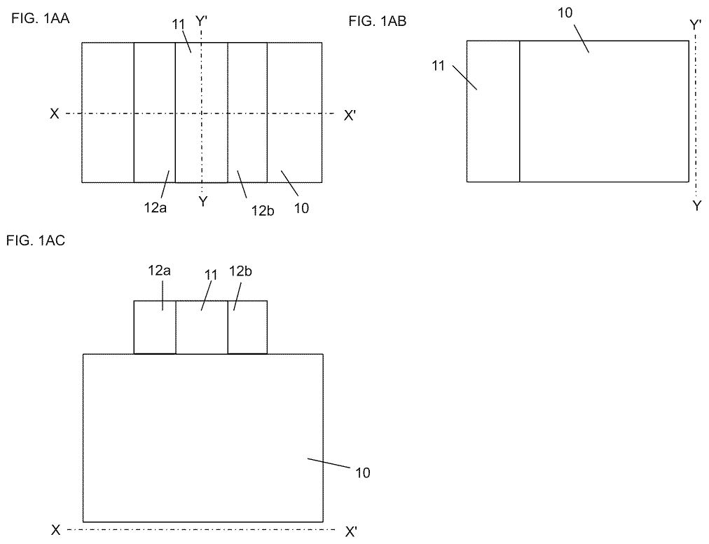

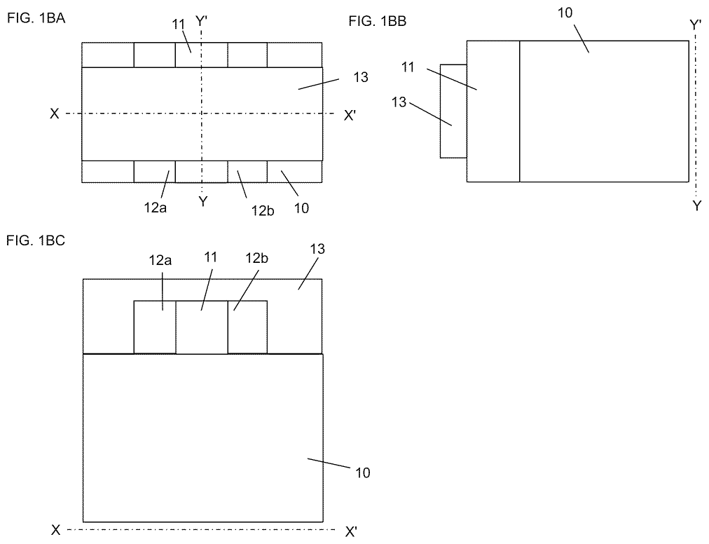

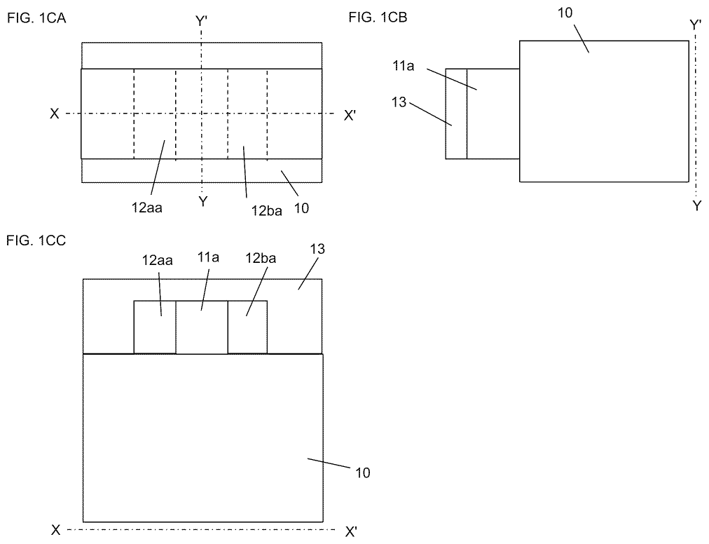

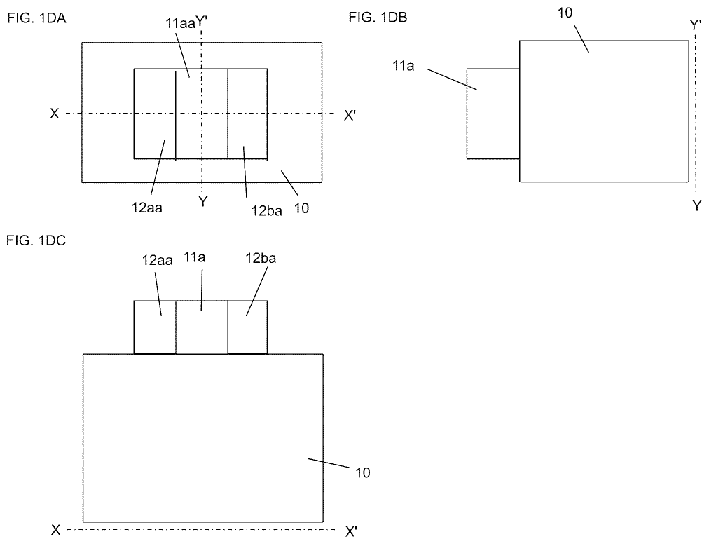

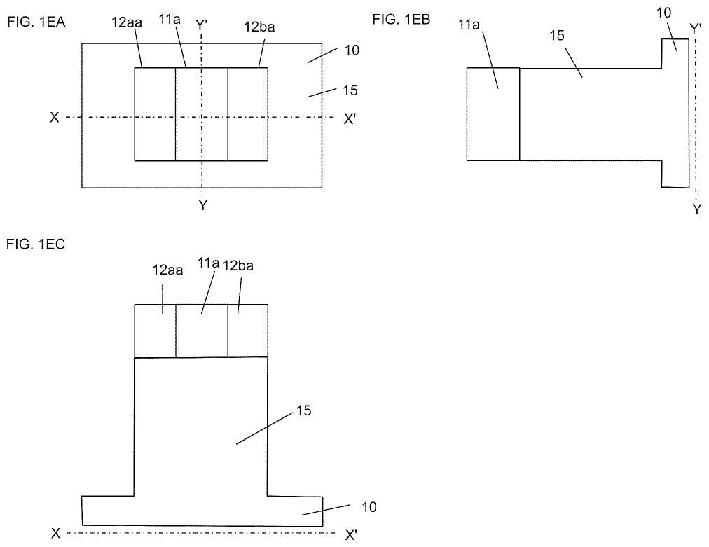

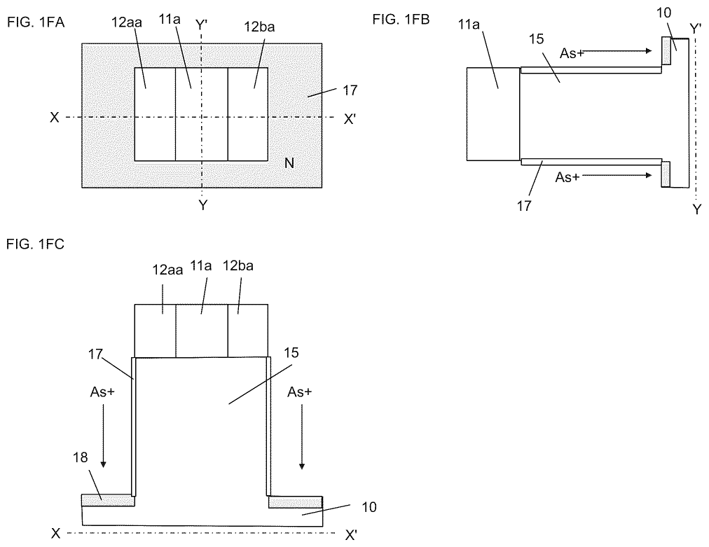

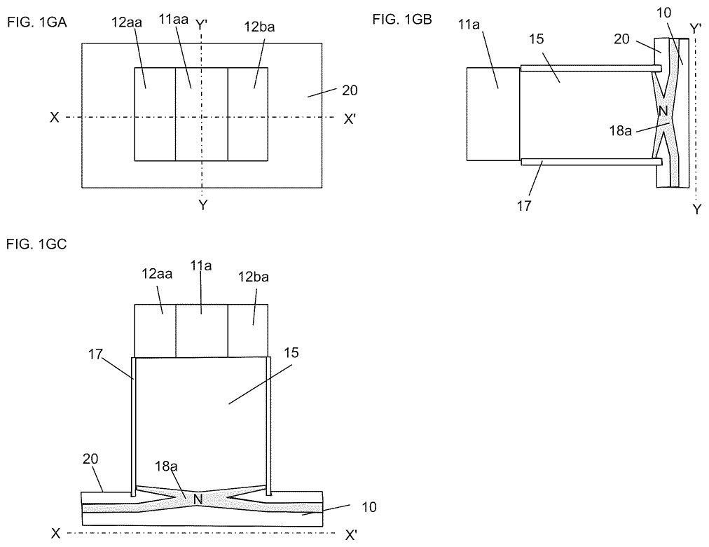

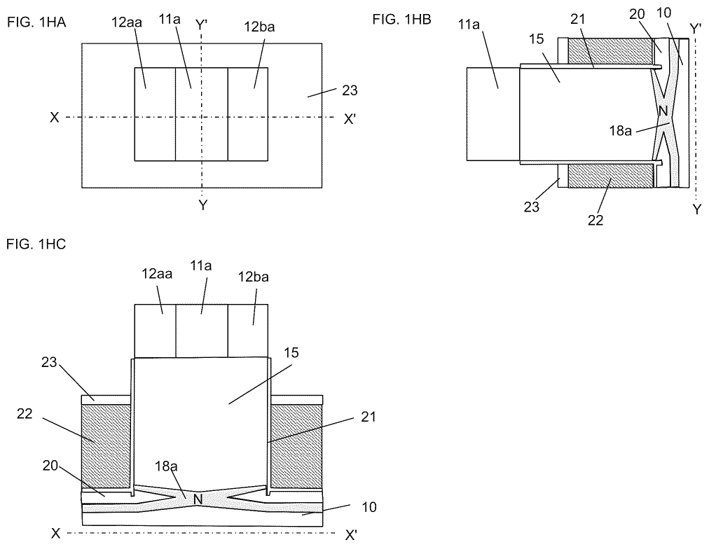

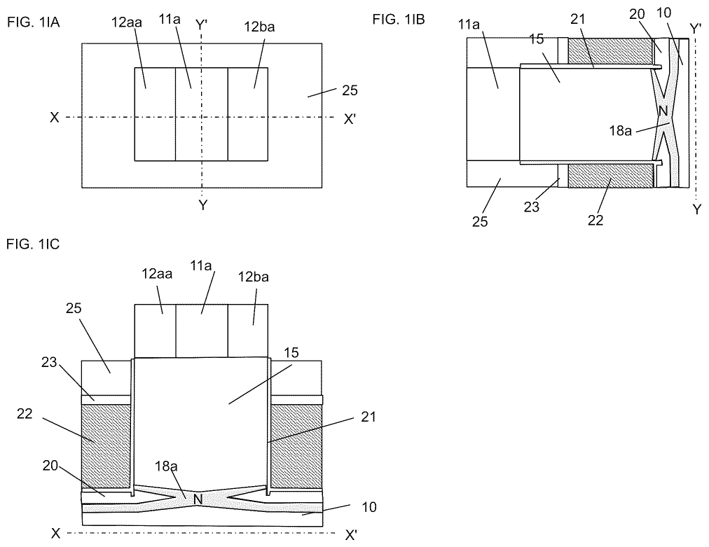

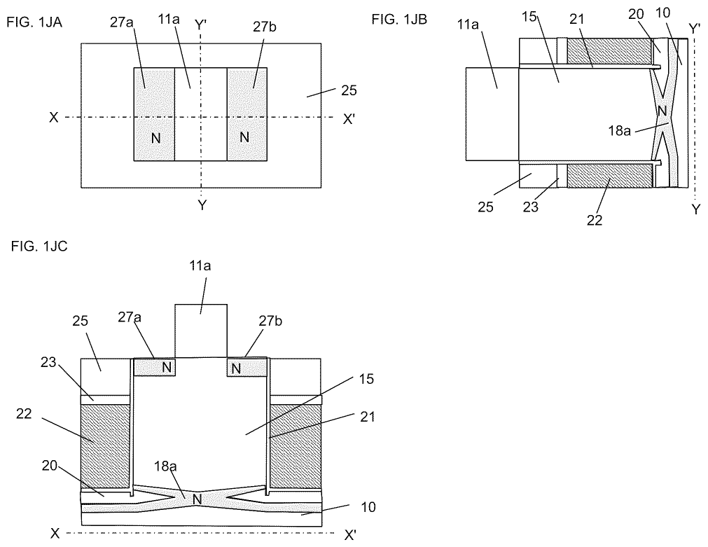

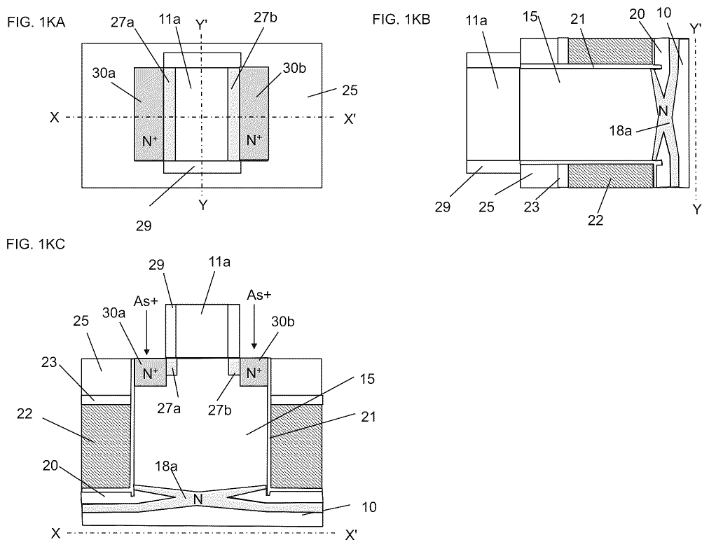

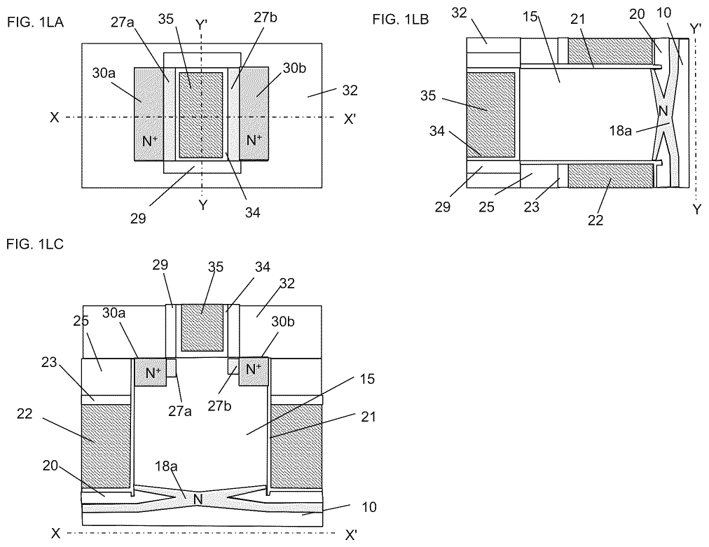

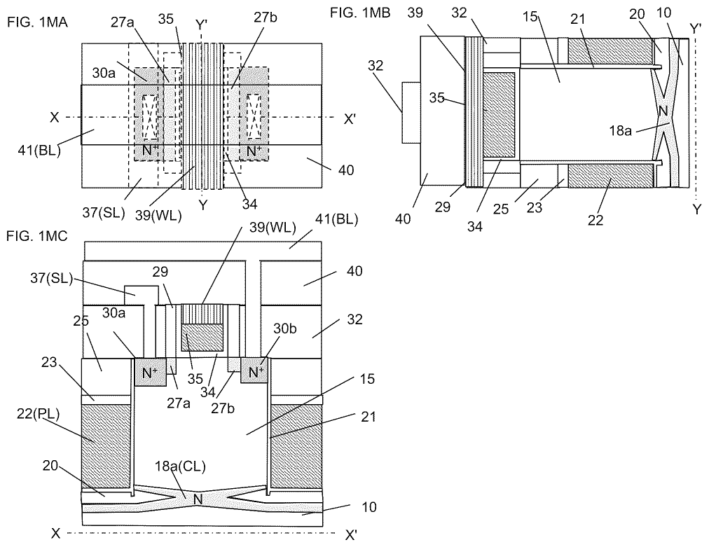

FIGS. 1AA to 1MC show a process for manufacturing a memory device using a semiconductor element according to this embodiment. Among these figures, figures with the suffix A are plan views of one memory cell, figures with the suffix B are sectional views taken along line Y-Y′ of the figures with the suffix A, and figures with the suffix C are sectional views taken along line X-X′ (an example of “second direction” in the claims) of the figures with the suffix A. In an actual memory device, such memory cells are arranged in a two-dimensional array.

As illustrated in FIGS. 1AA to 1AC, a first band-shaped material layer 11 (an example of “first band-shaped material layer” in the claims) extending in a line Y-Y′ direction (an example of “first direction” in the claims) is formed on a P layer 10 (an example of “semiconductor layer” in the claims), and then second band-shaped material layers 12a and 12b (examples of “second band-shaped material layer” in the claims) having an equal width in plan view are formed on both sides of the first band-shaped material layer 11. The second band-shaped material layers 12a and 12b are formed, for example, as follows: a material film is formed so as to cover the entire surface by chemical vapor deposition (CVD), and then the material film is etched by reactive ion etching (RIE) to form, on both sides of the first band-shaped material layer 11, the second band-shaped material layers 12a and 12b having an equal width. Thus, the second band-shaped material layers 12a and 12b are formed in a self-aligned manner with respect to the first band-shaped material layer 11. The phrase “formed in a self-aligned manner” means that the second band-shaped material layers 12a and 12b are formed at desired positions without using an additional lithography technique on the first band-shaped material layer 11. Forming the first band-shaped material layer 11 and the second band-shaped material layers 12a and 12b using different lithography processes will involve the occurrence of mask misalignment in the two lithography processes, leading to a decrease in the degree of integration of memory cells. The increase in the number of lithography processes will cause an increase in cost. The first band-shaped material layer 11 and the second band-shaped material layers 12a and 12b may each be formed of a plurality of material layers.

Next, as illustrated in FIGS. 1BA to 1BC, a band-shaped third material layer 13 (an example of “third band-shaped material layer” in the claims) covering the first band-shaped material layer 11 and the second band-shaped material layers 12a and 12b and extending in a line X-X′ direction (an example of “second direction” in the claims) perpendicular thereto in plan view is formed on the P layer 10. The band-shaped third material layer 13 may be constituted by a resist layer, an organic or inorganic material layer, or a material layer formed of a laminate thereof.

Next, as illustrated in FIGS. 1CA to 1CC, the first material layer 11 and the second material layers 12a and 12b are etched using the third material layer 13 as a mask to form a first mask material layer 11a (an example of “first mask material layer” in the claims) and second mask material layers 12aa and 12ba (examples of “second mask material layer” in the claims).

Next, as illustrated in FIGS. 1DA to 1DC, the third material layer 13 is removed. As a result, the first mask material layer 11a and the second mask material layers 12aa and 12ba having an equal width on both sides of the first mask material layer 11a are formed on the P layer 10 in plan view.

Next, as illustrated in FIGS. 1EA to 1EC, a P-layer semiconductor pillar 15 (an example of “semiconductor pillar” in the claims) is formed on the P layer 10 using the first mask material layer 11a and the second mask material layers 12aa and 12ba as etching masks. Thus, the P-layer semiconductor pillar 15 is formed in a self-aligned manner with respect to the first mask material layer 11a and the second mask material layers 12aa and 12ba.

Next, as illustrated in FIGS. 1FA to 1FC, for example, a silicon nitride (SiN) layer 17 is formed on a side surface of the P-layer semiconductor pillar 15. Next, for example, arsenic (As) ions are implanted, by ion implantation, on the P layer 10 at an outer peripheral portion of the P-layer semiconductor pillar 15 to form an N layer 18. Thus, the N layer 18 is formed in a self-aligned manner with respect to the first mask material layer 11a and the second mask material layers 12aa and 12ba. The N layer 18 may also be formed by ion implantation using ionic atoms other than As that can form the N layer 18. Alternatively, the N layer 18 may be formed using other methods such as solid-phase diffusion.

Next, as illustrated in FIGS. 1GA to 1GC, after the N layer 18 is spread into the P layer 10 and a bottom portion of the P-layer semiconductor pillar 15 by thermal diffusion, a thermally oxidized layer 20 is formed by thermal oxidation, and an N layer 18a (an example of “first impurity region” in the claims) connecting to the entire bottom portion of the P-layer semiconductor pillar 15 is also formed. Since the N layer 18a is formed so as to spread from the outer periphery of the bottom portion of the P-layer semiconductor pillar 15 to the inside of the bottom portion of the P-layer semiconductor pillar 15 by thermal diffusion, the N layer 18a is formed in a self-aligned manner with respect to the P-layer semiconductor pillar 15. Since the P-layer semiconductor pillar 15 is formed in a self-aligned manner with respect to the first mask material layer 11a and the second mask material layers 12aa and 12ba, the N layer 18 is also formed in a self-aligned manner with respect to the first mask material layer 11a and the second mask material layers 12aa and 12ba. The N layer 18a may be connected to the entire bottom portion of the P-layer semiconductor pillar 15 by the final process of the memory device. Instead of the P layer 10, a substrate formed using epitaxial crystal growth so as to be composed of a P layer, an N layer, and a P layer from bottom may be used, and the N layer in the substrate may be used as the N layer 18a. In this case, the N layer 18a is formed across the bottom portion of the P-layer semiconductor pillar 15 in plan view at the stage when the P-layer semiconductor pillar 15 is formed, and thus the N layer 18a is formed in a self-aligned manner with respect to the P-layer semiconductor pillar 15.

Next, as illustrated in FIGS. 1HA to 1HC, the SiN layer 17 is removed, and then a first gate insulating layer 21 (an example of “first gate insulating layer” in the claims) is formed on the side surface of the P-layer semiconductor pillar 15 and on the thermally oxidized layer 20 disposed at the outer peripheral portion of the P-layer semiconductor pillar 15. A first gate conductor layer 22 (an example of “first gate conductor layer” in the claims) and an insulating layer 23 on the first gate conductor layer 22 are formed so as to surround a lower side surface of the first gate insulating layer 21 covering the P-layer semiconductor pillar 15. Since the first gate insulating layer 21 is formed so as to surround the outer peripheral portion of the P-layer semiconductor pillar 15 without using a lithography technique, the first gate insulating layer 21 is formed in a self-aligned manner with respect to the P-layer semiconductor pillar 15. The first gate insulating layer 21 may be, for example, an oxidized insulating layer formed by oxidizing the surface of the P-layer semiconductor pillar 15. In this case, the first gate insulating layer 21 is not formed on the thermally oxidized layer 20. The first gate insulating layer 21 may be formed of a single layer or a plurality of layers. The insulating layer 23 may be omitted. The first gate conductor layer 22 may be formed in such a manner that a dummy material layer is first formed, and then in a subsequent step, the first gate conductor layer 22 is formed after the dummy material layer is removed.

Next, an insulating layer (not illustrated) is deposited on the entire surface by CVD. The insulating layer is polished by chemical mechanical polishing (CMP) so that the upper surface thereof is flush with the upper surfaces of the first mask material layer 11a and the second mask material layers 12aa and 12ba. Thereafter, as illustrated in FIGS. 1IA to 1IC, the insulating layer is etched by RIE to form an insulating layer 25 whose upper surface is substantially flush with the upper surface of the P-layer semiconductor pillar 15.

Next, as illustrated in FIGS. 1JA to 1JC, the second material layers 12a and 12b are removed. Using As ion implantation, N layers 27a and 27b containing a donor impurity are formed on upper surfaces of the P-layer semiconductor pillar 15 on both sides of the first material layer 11aa. Thus, the N layers 27a and 27b are formed in a self-aligned manner with respect to the first material layer 11aa and the P-layer semiconductor pillar 15.

Next, as illustrated in FIGS. 1KA to 1KC, a third material layer 29 is formed on a side surface of the first material layer 11a. The material layer 29 having an equal width is formed so as to surround the side surface of the first mask material layer 11a in plan view through, for example, CVD deposition of an insulating layer, polishing of the insulating layer by CMP, and etching of the insulating layer by RIE. Subsequently, N⁺ layers 30a and 30b, which are high-concentration impurity regions containing a large amount of donor impurity, are formed on upper surfaces of the P-layer semiconductor pillar 15 on both sides of the material layer 29 using As ion implantation. As a result, the N layers 27a and 27b, which are low-concentration impurity regions, are formed in top portions of the P-layer semiconductor pillar 15 disposed between the first mask material layer 11a and the N⁺ layers 30a and 30b in plan view. The material layer 29 is formed in a self-aligned manner with respect to the first mask material layer 11a. The N⁺ layers 30a and 30b are formed in a self-aligned manner with respect to the first mask material layer 11a, the material layer 29, and the P-layer semiconductor pillar 15. In this manner, a second impurity region (an example of “second impurity region” in the claims) composed of the N layer 27a and the N⁺ layer 30a and a third impurity region (an example of “third impurity region” in the claims) composed of the N layer 27b and the N⁺ layer 30b are formed in the top portions of the P-layer semiconductor pillar 15 on both sides of the first mask material layer 11a.

Next, as illustrated in FIGS. 1LA to 1LC, an insulating layer 32 is formed at an outer peripheral portion of the third material layer 29. The first mask material layer 11a is removed. A second gate insulating layer 34 (corresponding to “second gate insulating layer” in the claims) in contact with the inner side of the resulting hole (corresponding to “first hole” in the claims) and a second gate conductor layer 35 (corresponding to “second gate conductor layer” in the claims) in contact with the second gate insulating layer 34 are formed using, for example, atomic layer deposition (ALD). The second gate insulating layer 34 and the second gate conductor layer 35 are formed such that the upper surfaces thereof are substantially flush with the upper surface of the insulating layer 32. Since the second gate insulating layer 34 and the second gate conductor layer 35 are formed by deposition such as ALD in the hole formed by removing the first mask material layer 11a, the second gate insulating layer 34 and the second gate conductor layer 35 are formed in a self-aligned manner with respect to the first mask material layer 11a. The second gate insulating layer 34 and the second gate conductor layer 35 may each be formed of a single layer or a plurality of material layers.

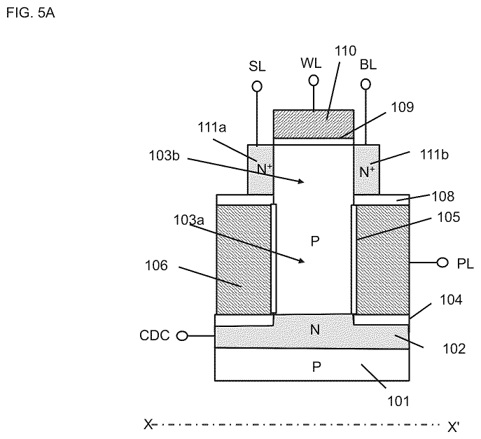

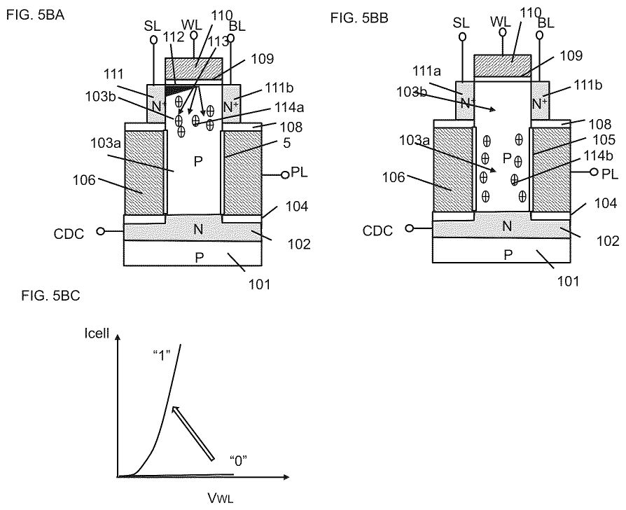

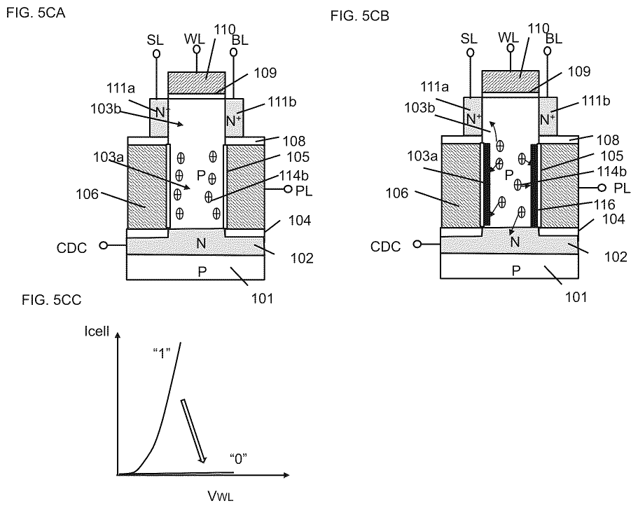

Next, as illustrated in FIGS. 1MA to 1MC, a groove extending in the line Y-Y′ direction is formed in upper portions of the second gate conductor layer 35 and the insulating layer 32, and then a metal wiring layer 39 in contact with the top of the second gate conductor layer 35 and extending in the line Y-Y′ direction in plan view is formed. A metal wiring layer 37 connecting to the N⁺ layer 30a is formed on the insulating layer 32 so as to extend in the line Y-Y′ direction. An insulating layer 40 is formed on the insulating layer 32. A metal wiring layer 41 connecting to the N⁺ layer 30b is formed on the insulating layer 40 so as to extend in the line X-X′ direction. The metal wiring layer 37 connects to a source line SL, the metal wiring layer 39 connects to a word line WL, the metal wiring layer 41 connects to a bit line BL, the first gate conductor layer 22 connects to a plate line PL, and the N layer 18a connects to a control line (CL). In this manner, a memory cell that performs the basic operations described with reference to FIGS. 5A to 5CC is formed on the P layer 10. Although the metal wiring layer 39 is formed by forming a groove extending in the line Y-Y′ direction in the second gate conductor layer 35 and the insulating layer 32 and then filling the groove with a metal layer, the metal wiring layer 39 may be formed of a metal wiring layer in contact with the second gate conductor layer 35 whose upper surface is unetched and connecting to the insulating layer 32 without forming the groove. The metal wiring layer 39 may be formed by other methods. In FIGS. 1MA to 1MC, both ends of the metal wiring layer 39 in the line X-X′ direction are located at the same position as that of both ends of the second gate conductor layer 35, but may be located inside the second gate conductor layer 35. These also apply to other embodiments. Although the metal wiring layer 39 and the metal wiring layer 37 are formed in parallel in the line Y-Y′ direction on the insulating layer 32, the wiring height in the vertical direction may be varied so as to reduce the capacitive coupling between the source line SL and the word line WL.

In FIGS. 1AA to 1AC, a material layer that serves as a stopper for etching of the first material layer 11 and the second material layers 12a and 12b in FIGS. 1CA to 1CC may be provided on the P layer 10 underlying the first band-shaped material layer 11 and the second band-shaped material layers 12a and 12b. The first mask material layer 11a and the second mask material layers 12aa and 12ba may be covered with a mask material layer for reducing an unwanted thickness reduction in the etching process after the formation or subjected to chemical or physical treatment.

In the manufacturing method according to this embodiment, the N layers 27a and 27b and the N⁺ layers 30a and 30b are first formed with the first mask material layer 11a left and the second mask material layers 12aa and 12ba removed, and then the second gate insulating layer 34 and the second gate conductor layer 35 are formed. Alternatively, after the second gate insulating layer 34 and the second gate conductor layer 35 are formed with the second mask material layers 12aa and 12ba left and the first mask material layer 11a removed, the second mask material layers 12aa and 12ba are removed, and the N layers 27a and 27b and the N⁺ layers 30a and 30b may be formed there.

In FIGS. 1KA to 1MC, the N layers 27a and 27b are formed on upper surfaces of the P-layer semiconductor pillar 15 between the N⁺ layers 30a and 30b and the second gate insulating layer 34. Alternatively, the N layers 27a and 27b may be formed so as to surround the entire side surfaces of the N⁺ layers 30a and 30b. The N layers 27a and 27b, which are low-concentration impurity regions, need not be subjected to ion implantation of, for example, arsenic (As) or phosphorus (P). In this case, the bottom of the material layer 29 on the side surface of the first material layer 11a corresponds to the upper surface of the P-layer semiconductor pillar 15. The low-concentration impurity regions also include a state of being undoped with additional impurities. In this case, the ON-state current decreases, but the electric field intensity at top portions of the P-layer semiconductor pillar 15 between the second gate insulating layer 34 and the N⁺ layers 30a and 30b is reduced. This can improve memory data retention characteristics. Without performing ion implantation, the conditions of heat treatment after the formation of the N⁺ layers 30a and 30b may be set such that the ON-state current and the retention characteristics are optimal considering the overall donor impurity concentration distribution in the regions of the N layers 27a and 27b. There may exist, in a region below the third material layer 29 and adjacent to the gate conductor layer 35 in plan view, a top portion of the P-layer semiconductor pillar 15 where donor impurity atoms are not diffused. These also apply to Examples described later.

While this embodiment has been described in the context where the N⁺ layers 30a and 30b are formed by ion implantation, the N⁺ layers 30a and 30b may be formed using, for example, selective epitaxial crystal growth and a subsequent heat treatment process. The connections between the metal wiring layer 37 and the N⁺ layer 30a and between the metal wiring layer 41 and the N⁺ layer 30b may be provided not only on upper surfaces but also on side surfaces of the N⁺ layers 30a and 30b. This also applies to Examples described later.

In this embodiment, the case where the first gate conductor layer 22 is formed so as to surround the entire side surface of the first gate insulating layer 21 in plan view has been described. Alternatively, the first gate conductor layer 22 may be divided into two in plan view. A synchronous or asynchronous drive voltage may be applied to the two divided first gate conductor layers. This also allows normal memory operation. The first gate conductor layer 22 may also be divided into two in the vicinity of the center of the second gate conductor layer 35 on line X-X′ in plan view. A fixed voltage which does not vary with time or zero voltage may be applied to one of the divided gate conductor the layers closer to the N⁺ layer 30b connecting to the bit line BL. This can, for example, provide one of the first gate conductor layers to which zero voltage is applied with an electrostatic shielding effect to stabilize the floating body voltage of the P-layer semiconductor pillar 15 where a group of holes serving as signal charges are stored. This also applies to Examples described later.

In FIGS. 1EA to 1EC, the section of the P-layer semiconductor pillar 15 formed by etching is rectangular, but it may be trapezoidal. This also applies to Examples described later.

Although the first gate insulating layer 21 is formed so as to extend above the first gate conductor layer 22 in the vertical direction in this embodiment, the gate insulating layer need only be high enough to cover the first gate conductor layer 22, and thus the portion located higher than the upper surface of the first gate conductor layer 22 need not be present. This also applies to Examples described later.

The method for manufacturing a memory cell according to this embodiment is characterized in that the P-layer semiconductor pillar 15, the first gate insulating layer 21, the first gate conductor layer 22, the second gate insulating layer 34, the second gate conductor layer 35, the N layers 18a, 27a, and 27b, and the N⁺ layers 30a and 30b, which are all elements constituting the memory cell, are formed in a self-aligned manner using the first mask material layer 11a and the second mask material layers 12aa and 12ba formed in a self-aligned manner. Specifically,

(1) The first mask material layer 11a and the second mask material layers 12aa and 12ba are formed without using lithography processes with different patterns and formed in a self-aligned manner (FIGS. 1AA to 1AC and FIGS. 1BA to 1BC).

(2) Since the P-layer semiconductor pillar 15 is formed using the first mask material layer 11a and the second mask material layers 12aa and 12ba as etching masks, the first mask material layer 11a, the second mask material layers 12aa and 12ba, and the P-layer semiconductor pillar 15 are formed in a self-aligned manner (FIGS. 1EA to 1EE).

(3) The N layer 18 formed by ion implantation using the first mask material layer 11a and the second mask material layers 12aa and 12ba as masks is thermally diffused to form the N layer 18a extending to the bottom portion of the P-layer semiconductor pillar 15. Thus, the N layer 18a is formed in a self-aligned manner with respect to the first mask material layer 11a, the second mask material layers 12aa and 12ba, and the P-layer semiconductor pillar 15 (FIGS. 1FA to 1FC and FIGS. 1GA to 1GC).

(4) The first gate insulating layer 21 and the first gate conductor layer 22 are formed in a self-aligned manner so as to surround the P-layer semiconductor pillar 15 without using a lithography process (FIGS. 1HA to 1HC).

(5) The N layers 27a and 27b, which are LDD regions, and the N⁺ layers 30a and 30b disposed outside the N layers 27a and 27b are formed in a self-aligned manner with respect to the first mask material layer 11a (FIGS. 1JA to 1JC and FIGS. 1KA to 1KC).

(6) Since the second gate insulating layer 34 and the second gate conductor layer 35 are buried in the hole formed by removing the first mask material layer 11a, the second gate insulating layer 34 and the second gate conductor layer 35 are formed in a self-aligned manner with respect to the first mask material layer 11a (FIGS. 1LA to 1LC).

With these features, a lower cost due to a reduction in the number of lithography processes and a memory cell with a higher degree of integration can be achieved.

The memory cell according to this embodiment is characterized in that a top section of a portion of the P-layer semiconductor pillar 15 that is surrounded by the first gate conductor layer 22 and a bottom section of a portion of the P-layer semiconductor pillar 15 that is in contact with the top section and includes the N⁺ layers 30a and 30b overlap each other with a substantially equal shape in plan view.

### Second Embodiment

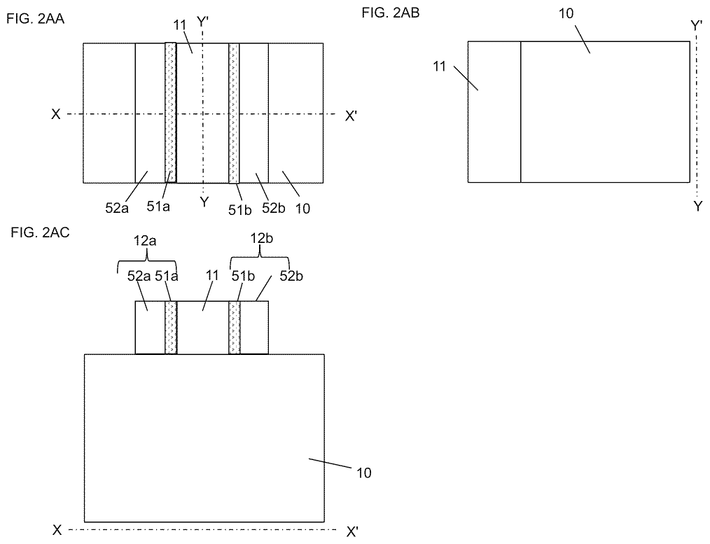

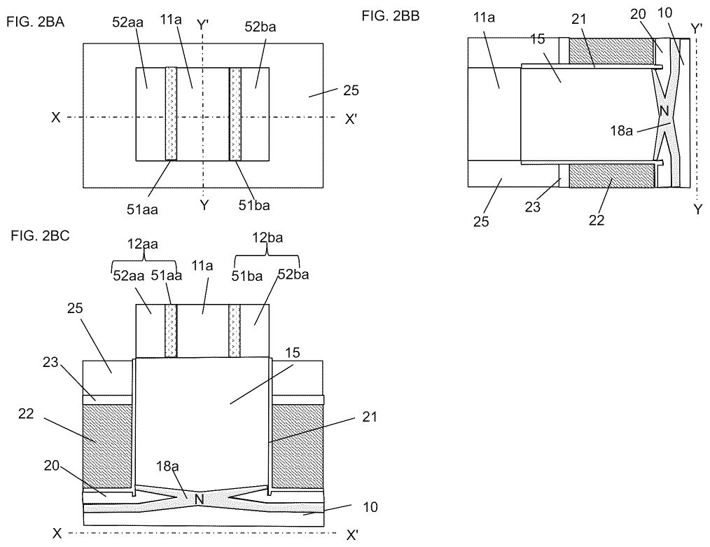

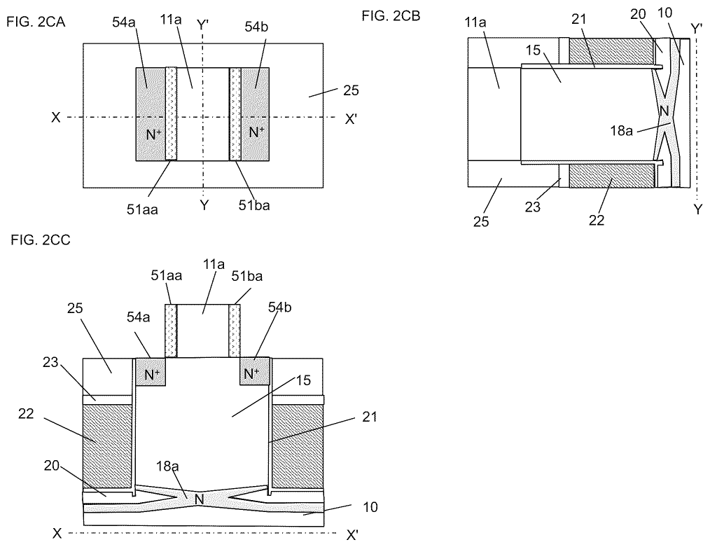

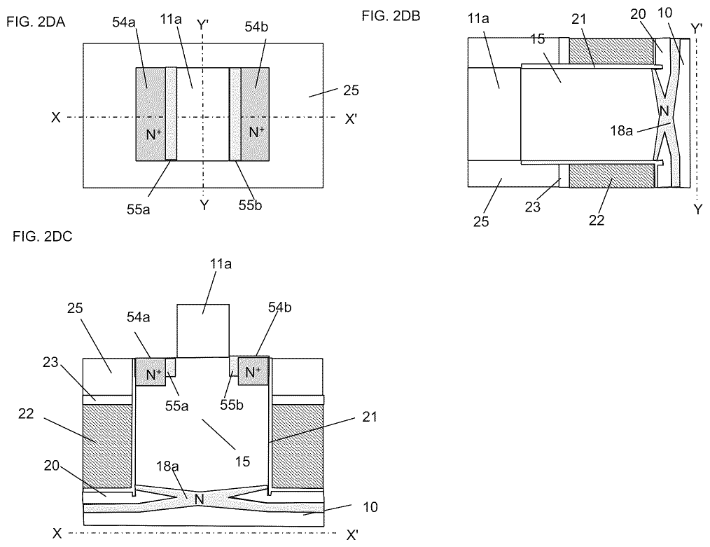

FIGS. 2AA to 2DC illustrate a method for manufacturing a memory device using a semiconductor element according to this embodiment. Among these figures, figures with the suffix A are plan views of one memory cell, figures with the suffix B are sectional views taken along line Y-Y′ of the figures with the suffix A, and figures with the suffix C are sectional views taken along line X-X′ of the figures with the suffix A. In an actual memory device, such memory cells are arranged in a two-dimensional array.

As illustrated in FIGS. 2AA to 2AC, band-shaped material layers 51a and 51b having an equal width and band-shaped material layers 52a and 52b having an equal width are formed on both sides of a first band-shaped material layer 11. Similarly to the second band-shaped material layers 12a and 12b illustrated in FIGS. 1AA to 1AC, the band-shaped material layers 51a and 51b are formed, for example, as follows: a material film is formed so as to cover the entire surface by CVD, and then the material film is etched by RIE to form the band-shaped material layers 51a and 51b on both sides of the first band-shaped material layer 11. The band-shaped material layers 52a and 52b are then formed on both sides of the band-shaped material layers 51a and 51b in the same manner as the band-shaped material layers 51a and 51b are formed. The band-shaped material layers 51a and 52a correspond to the second band-shaped material layer 12a in FIGS. 1AA to 1AC, and the band-shaped material layers 51b and 52b correspond to the second band-shaped material layer 12b in FIGS. 1AA to 1AC. Thus, the band-shaped material layers 51a, 51b, 52a, and 52b are formed in a self-aligned manner with respect to the first band-shaped material layer 11.

Next, the same steps as those in FIGS. 1BA to 1IC are performed. As a result, as illustrated in FIGS. 2BA to 2BC, a first mask material layer 11a and material layers 51aa, 51ba, 52aa, and 52ba that are rectangular in plan view are formed on the P-layer semiconductor pillar 15. The mask material layers 52aa and 52ba having an equal width are formed outside the mask material layers 51aa and 51ba, respectively. The mask material layers 51aa and 52aa correspond to the second mask material layer 12aa in FIGS. 1IA to 1IC, and the mask material layers 51ba and 52ba correspond to the second mask material layer 12ba.

Next, as illustrated in FIGS. 2CA to 2CC, the mask material layers 52aa and 52ba are removed, and then N⁺ layers 54a and 54b are formed in top portions of the P-layer semiconductor pillar 15 that are disposed outside the mask material layers 51aa and 51ba by, for example, ion implantation.

Next, as illustrated in FIGS. 2DA to 2DC, the mask material layers 51aa and 51ba are removed, and then, by ion implantation, donor impurity ionic atoms at a higher concentration than that in the formation of the N⁺ layers 54a and 54b are implanted in top portions of the P-layer semiconductor pillar 15 that are disposed outside the first mask material layer 11a. As a result, N layers 55a and 55b are formed between the first mask material layer 11a and the N⁺ layer 54a and between the first mask material layer 11a and the N⁺ layer 54b, respectively, in plan view. Thus, the N⁺ layers 54a and 54b and the N layers 55a and 55b are formed in a self-aligned manner with respect to the first mask material layer 11a in plan view. Thereafter, the same steps as illustrated in FIGS. 1LA to 1MC are performed, whereby the same memory cell as illustrated in FIGS. 1MA to 1MC is formed on the Player 10. The formation of the N layers 55a and 55b may be performed by heat treatment after the formation of the N⁺ layers 54a and 54b without removing the mask material layers 51aa and 51ba. In the method using heat treatment, the N layers need not extend over the whole areas of the mask material layers 51aa and 51ba in plan view.

In this embodiment, as compared with the first embodiment, the N layers 55a and 55b (corresponding to the N layers 27a and 27b in FIGS. 1MA to 1MC) and the N⁺ layers 54a and 54b (corresponding to the N⁺ layers 30a and 30b in FIGS. 1MA to 1MC) are formed in the reverse order. However, the mask material layers 51aa, 51ba, 52aa, and 52ba for forming the N layers 55a and 55b and the N⁺ layers 54a and 54b are still formed in a self-aligned manner with respect to the first mask material layer 11a. If the mask material layers 51aa and 52aa are considered as the second mask material layer 12aa and the mask material layers 51ba and 52ba are considered as the second mask material layer 12ba, the first embodiment and the second embodiment are substantially the same. Thus, in the second embodiment, a lower cost and a memory cell with a higher degree of integration can be achieved as in the first embodiment.

### Third Embodiment

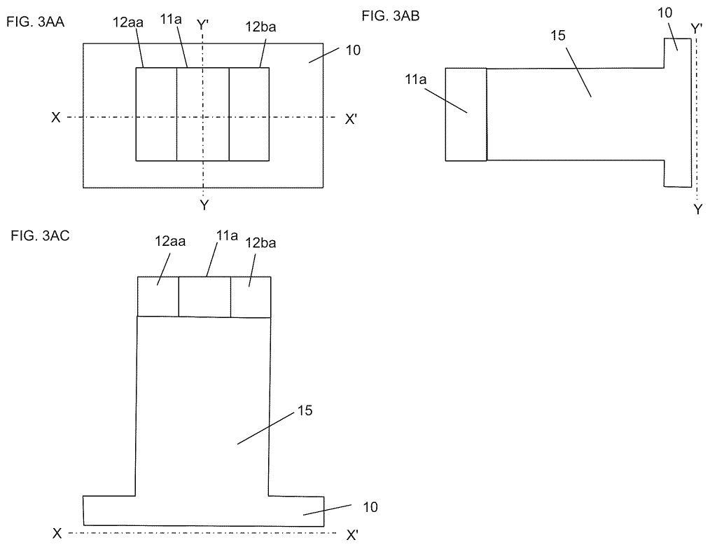

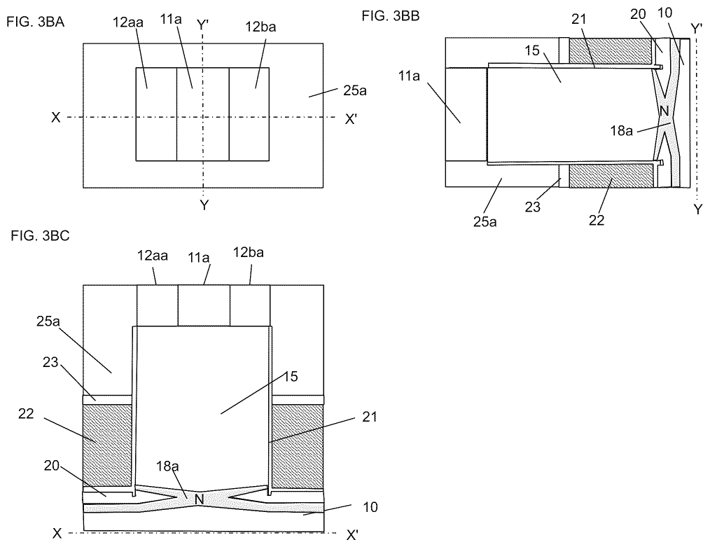

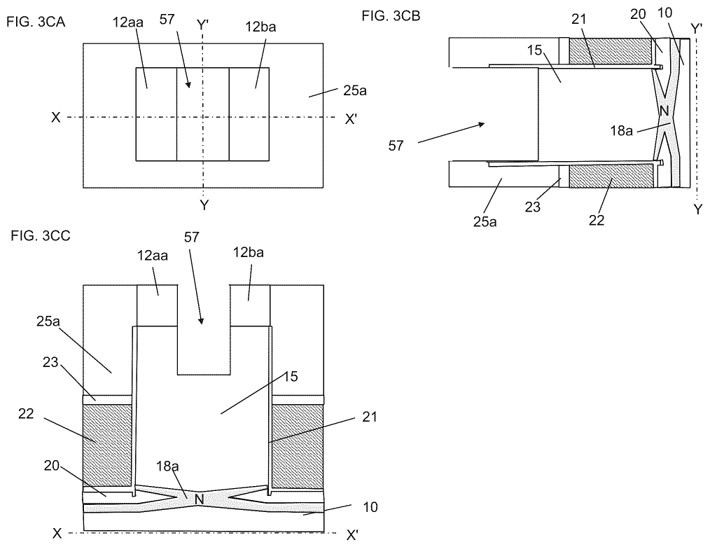

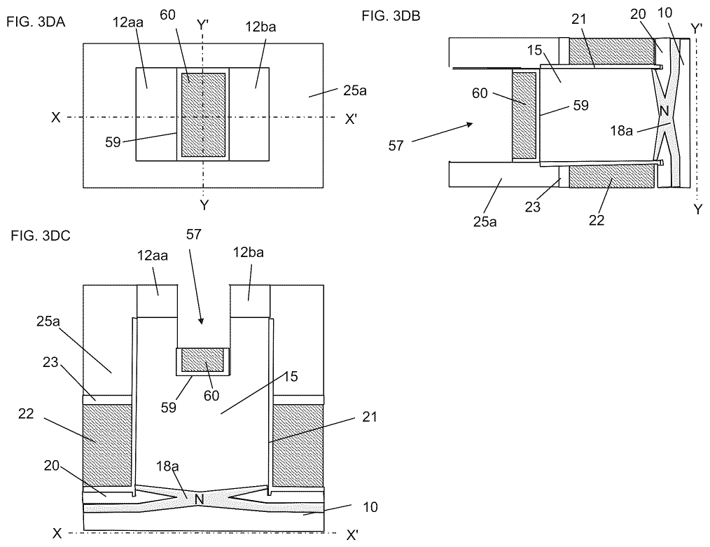

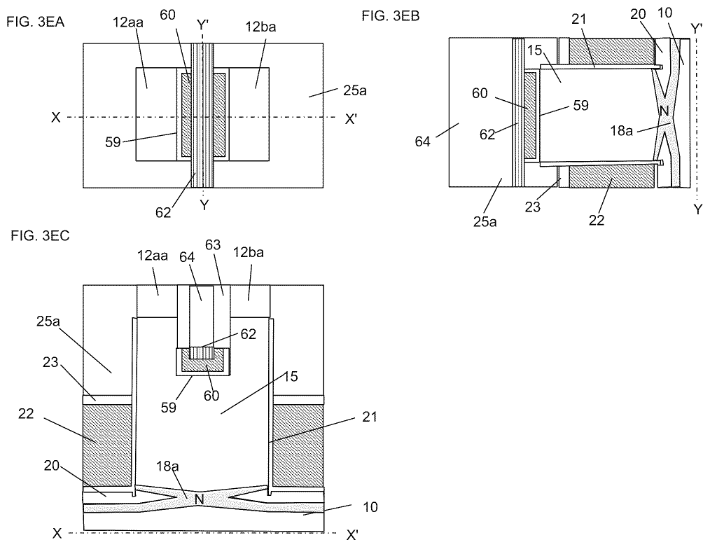

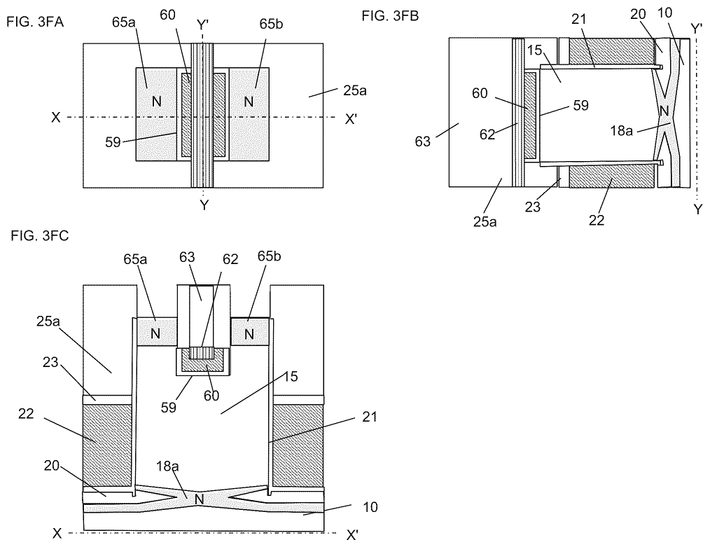

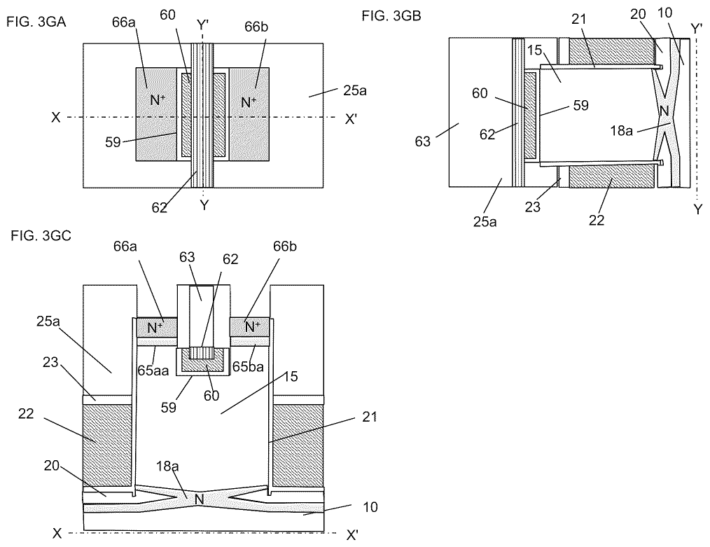

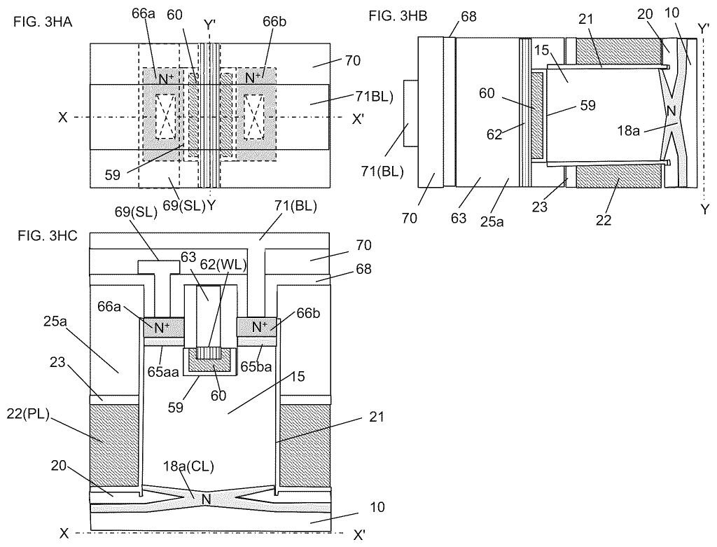

FIGS. 3AA to 3HC illustrate a method for manufacturing a memory device using a semiconductor element according to this embodiment. Among these figures, figures with the suffix A are plan views of one memory cell, figures with the suffix B are sectional views taken along line Y-Y′ of the figures with the suffix A, and figures with the suffix C are sectional views taken along line X-X′ of the figures with the suffix A. In an actual memory device, such memory cells are arranged in a two-dimensional array.

As illustrated in FIGS. 3AA to 3AC, in the same manner as in FIGS. 1EA to 1EC, a P layer 10 is etched by RIE using a first mask material layer 11a and second mask material layers 12aa and 12ba as etching masks to form a P-layer semiconductor pillar 15.

Next, the same steps as those in FIGS. 1FA to 1HC are performed to form an N layer 18a, a first gate insulating layer 21, a first gate conductor layer 22, and an insulating layer 23 on the P layer 10 as illustrated in FIGS. 3BA to 3BC. Subsequently, an insulating layer 25a whose upper surface is flush with the upper surfaces of the first mask material layer 11a and the second mask material layers 12aa and 12ba is formed so as to surround the first mask material layer 11a, the second mask material layers 12aa and 12ba, and the P-layer semiconductor pillar 15.

Next, as illustrated in FIGS. 3CA to 3CC, the first mask material layer 11a is removed. Subsequently, a top portion of the P-layer semiconductor pillar 15 is etched using the second mask material layers 12aa and 12ba and the insulating layer 25a as etching masks to form a hole 57. The bottom of the hole 57 is located higher than the upper surface of the first gate conductor layer 22.

Next, a gate insulating layer (not illustrated) and a gate conductor layer (not illustrated) are formed on the inner side surface of the hole 57 and the upper surface of the insulating layer 25a by, for example, ALD. The gate insulating layer and the gate conductor layer are polished by CMP such that their upper surfaces are flush with the upper surface of the insulating layer 25a. The gate insulating layer and the gate conductor layer are etched by RIE from above to form a second gate insulating layer 59 and a second gate conductor layer 60 in the hole 57, as illustrated in FIGS. 3DA to 3DC.

Next, as illustrated in FIGS. 3EA to 3EC, an insulating layer 63 is formed in the hole 57. A hole (not illustrated) whose bottom is located on the second gate conductor layer 60 and which extends in the line Y-Y′ direction is formed by lithography and RIE. In this hole, a metal layer (not illustrated) whose upper surface is flush or nearly flush with the upper surface of the insulating layer 25a is formed. The metal layer is etched by RIE from above to form a metal wiring layer 62 extending in the line Y-Y′ direction. An insulating layer 64 is formed on the metal wiring layer 62. The metal wiring layer 62 may be made of the same conductor material as that of the second gate conductor layer 60. The metal wiring layer 62 may be formed such that its width in the line X-X′ direction is the same as that of the second gate conductor layer 60.

Next, as illustrated in FIGS. 3FA to 3FC, the second mask material layers 12aa and 12ba are removed by etching, and then N layers 65a and 65b are formed in the two exposed top portions of the P-layer semiconductor pillar 15 by ion implantation. The bottom portions of the N layers 65a and 65b are located near the top portion of the second gate conductor layer 60. In practice, the N layers 65a and 65b have an impurity concentration distribution in the vertical direction, and thus the positional relationship between the N layers 65a and 65b and the second gate conductor layer 60 in the vertical direction is adjusted according to the design requirements for a MOS transistor.

Next, as illustrated in FIGS. 3GA to 3GC, N⁺ layers 66a and 66b are formed on the two exposed top portions of the P-layer semiconductor pillar 15 by ion implantation. The N⁺ layers 66a and 66b are formed such that their bottom portions are located higher than the bottom portions of the N layers 65a and 65b. As a result, N layers 65aa and 65ba are formed between the N⁺ layer 66a and the P-layer semiconductor pillar 15 and between the N⁺ layer 66b and the P-layer semiconductor pillar 15, respectively. The N⁺ layers 66a and 66b may be formed using other methods such as selective epitaxial crystal growth.

Next, as illustrated in FIGS. 3HA to 3HC, an insulating layer 68 is formed over the entire surface, and then a wiring metal layer 69 connected to the N⁺ layer 66a and extending in the line Y-Y′ direction is formed. An insulating layer 70 is formed over the entire surface, and then a wiring metal layer 71 connected to the N⁺ layer 66b and extending in the line X-X′ direction is formed. The N layer 18a is connected to a control line CL, the first gate conductor layer 22 is connected to a plate line PL, the metal wiring layer 62 is connected to a word line WL, the N⁺ layer 66a is connected to a source line SL, and the N⁺ layer 66b is connected to a bit line BL. In this manner, a memory cell that performs the same basic operations as illustrated in the first embodiment is formed on the P layer 10. In this memory cell, a MOS transistor in which a channel between the N⁺ layers 66a and 66b has a U-shaped section is formed.

In the manufacturing method according to this embodiment, the first mask material layer 11a is first removed while the second mask material layers 12aa and 12ba are left, and then the second gate insulating layer 59 and the second gate conductor layer 60 are formed in the hole 57 formed. Thereafter, the N layers 65aa and 65ba and the N⁺ layers 66a and 66b are formed. Alternatively, the following procedure may be used: the second mask material layers 12aa and 12ba are first removed while the first mask material layer 11a is left, and then the N layers 65aa and 65ba and the N⁺ layers 66a and 66b are formed; subsequently, the first mask material layer 11a is removed, and then the second gate insulating layer 59 and the second gate conductor layer 60 are formed in the hole 57 formed.

While this embodiment has been described in the context where the channel of the MOS transistor has a U-shaped section, the channel may be rectangular so as to increase the effective channel length, trapezoidal, V-shaped, or balloon-shaped.

The method for manufacturing a memory cell according to this embodiment, as with the first embodiment, is characterized in that using the first mask material layer 11a and the second mask material layers 12aa and 12ba formed in a self-aligned manner, in plan view, the second gate insulating layer 59 and the second gate conductor layer 60 are formed where the first mask material layer 11a has been located, and the N⁺ layers 66a and 66b and the N layers 65aa and 65ba are formed in a self-aligned manner where the second mask material layers 12aa and 12ba have been located; thus, the P-layer semiconductor pillar 15, the first gate insulating layer 21, the first gate conductor layer 22, the second gate insulating layer 59, the second gate conductor layer 60, the N layers 18a, 65aa, and 65ba, and the N⁺ layers 66a and 66b, which are all elements constituting the memory cell, are formed in a self-aligned manner.

### Fourth Embodiment

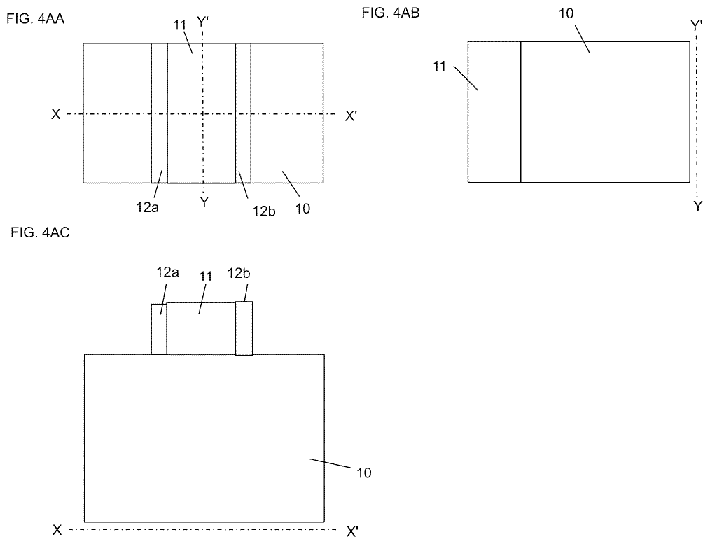

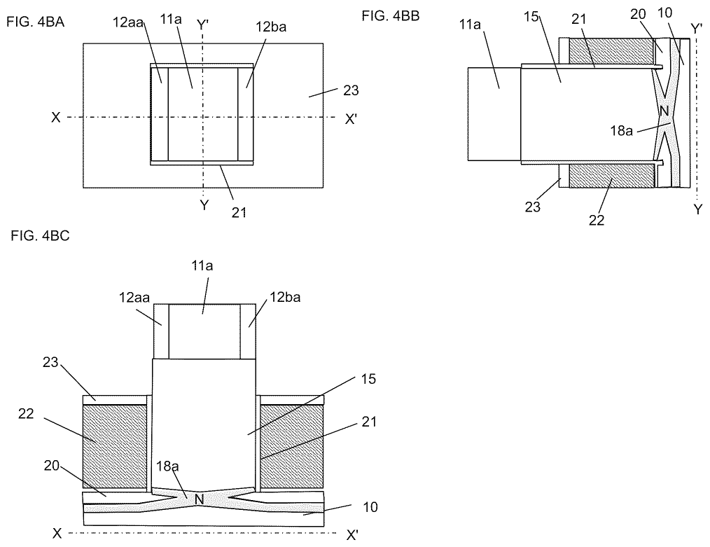

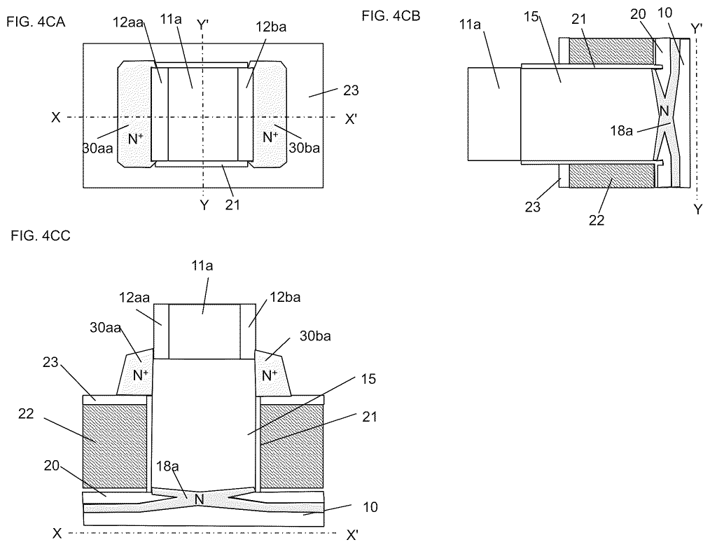

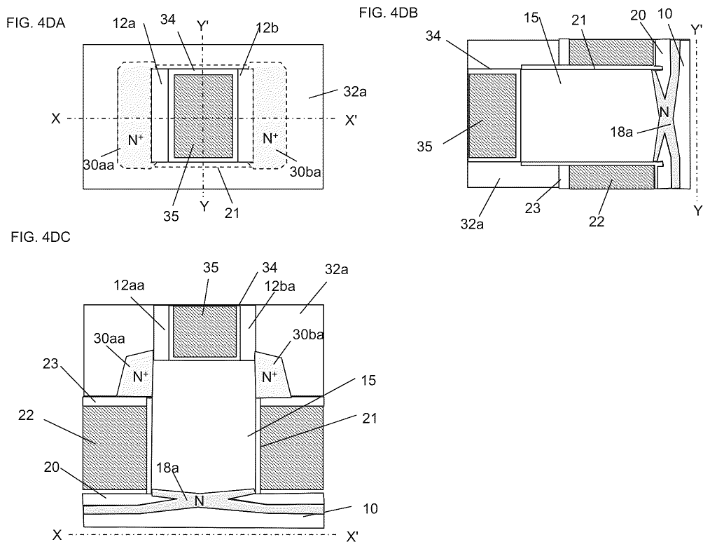

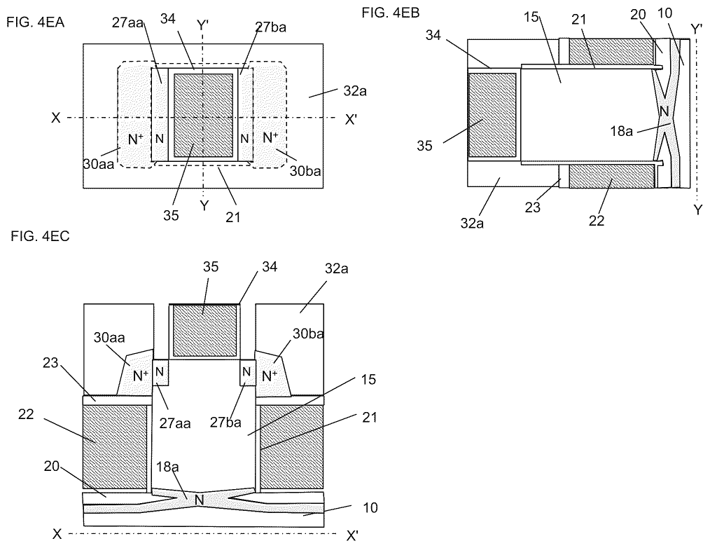

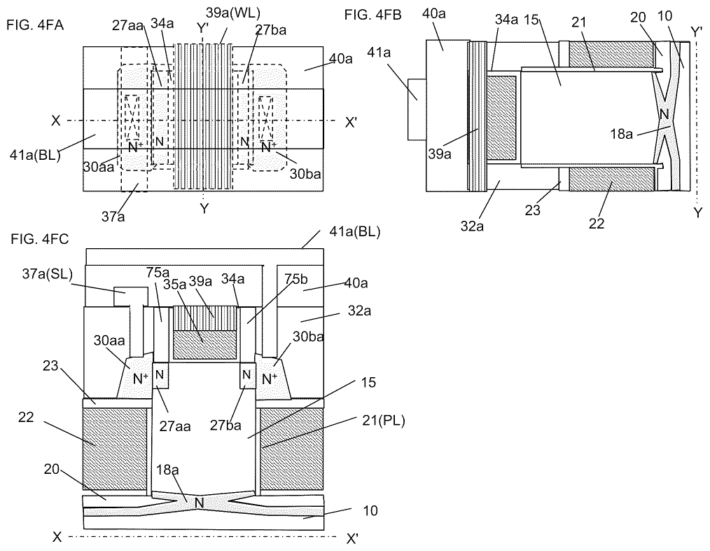

FIGS. 4AA to 4FC illustrate a method for manufacturing a memory device using a semiconductor element according to this embodiment. Among these figures, figures with the suffix A are plan views of one memory cell, figures with the suffix B are sectional views taken along line Y-Y′ of the figures with the suffix A, and figures with the suffix C are sectional views taken along line X-X′ of the figures with the suffix A. In an actual memory device, such memory cells are arranged in a two-dimensional array.

The same steps as the steps illustrated in FIGS. 1AA to 1DC are performed to form, on a P layer 10, a first band-shaped mask material layer 11 and second band-shaped mask material layers 12a and 12b having an equal width on both sides of the first band-shaped mask material layer 11 in plan view, as illustrated in FIGS. 4AA to 4AC.

Next, the same steps as the steps illustrated in FIGS. 1EA to 1HC are performed. As a result, an N layer 18a is formed on the P layer 10 and in a bottom portion of a P-layer semiconductor pillar 15 as illustrated in FIGS. 4BA to 4BC. A first gate insulating layer 21 is formed on a side surface of the P-layer semiconductor pillar 15 and on a thermally oxidized layer 20 disposed at an outer peripheral portion of the P-layer semiconductor pillar 15. A first gate conductor layer 22 is formed so as to surround a lower side surface of the first gate insulating layer 21 covering the P-layer semiconductor pillar 15, and an insulating layer 23 is formed on the first gate conductor layer 22. The first gate insulating layer 21 in the line X-X′ direction disposed above the insulating layer 23 is removed to expose a surface at this portion of the P-layer semiconductor pillar 15. The removal of the first gate insulating layer 21 in the line X-X′ direction may be performed using a lithography technique and a technique of etching the first gate insulating layer 21. Other methods may also be used.

Next, as illustrated in FIGS. 4CA to 4CC, N⁺ layers 30aa and 30ba containing a donor impurity are formed in contact with the side surface of the P-layer semiconductor pillar 15 exposed in the line X-X′ direction using selective epitaxial crystal growth.

Next, as illustrated in FIGS. 4DA to 4DC, an insulating layer 32a whose upper surface is flush with the upper surfaces of the first mask material layer 11a and the second mask material layers 12aa and 12ba is formed. The first mask material layer 11a is removed. In a hole formed by removing the first mask material layer 11a, a second gate insulating layer 34 and a second gate conductor layer 35 in contact with the second gate insulating layer 34 are formed using, for example, ALD. The second gate insulating layer 34 and the second gate conductor layer 35 are formed such that their upper surfaces are substantially flush with the upper surface of the insulating layer 32a.

Next, as illustrated in FIGS. 4EA to 4EC, the second mask material layers 12aa and 12ba are removed, and in top portions of the P-layer semiconductor pillar 15 at the bottom of the resulting hole, N layers 27aa and 27ab are formed using ion implantation.

Next, as illustrated in FIGS. 4FA to 4FC, a metal wire 39a in contact with the second gate conductor layer 35 and extending in the line Y-Y′ direction in plan view is formed. A metal wiring layer 37a connecting to the N⁺ layer 30aa is formed on the insulating layer 32a so as to extend in the line Y-Y′ direction. An insulating layer 40a is formed on the insulating layer 32a. A metal wiring layer 41a connecting to the N⁺ layer 30ba is formed on the insulating layer 40a so as to extend in the line X-X′ direction. The metal wiring layer 37a connects to a source line SL, the metal wire 39a connects to a word line WL, the metal wiring layer 41a connects to a bit line BL, the first gate conductor layer 22 connects to a plate line PL, and the N layer 18a connects to a control line CL. In this manner, a memory cell that performs the basic operations described with reference to FIGS. 5A to 5CC is formed on the P layer 10.

In FIGS. 4EA to 4EC, the second mask material layers 12aa and 12ba are removed, and in top portions of the P-layer semiconductor pillar 15 at the bottom of the resulting hole, the N layers 27aa and 27ab are formed using ion implantation. Alternatively, the N layers 27aa and 27ab may be formed after the N⁺ layers 30aa and 30ba are formed. Alternatively, without performing ion implantation, N layers may be formed in parts or the whole of top portions of the P-layer semiconductor pillar 15 that underlie the second mask material layers 12aa and 12ba by performing a heat treatment process after forming the N⁺ layers 30aa and 30ba. In this case, the step of removing the second mask material layers 12aa and 12ba illustrated in FIGS. 4EA to 4EC is unnecessary. Even if a special heat treatment process is not performed after the N⁺ layers 30aa and 30ba are formed, low-concentration impurity regions will be partially formed in the top portions of the P-layer semiconductor pillar 15 that underlie the second mask material layers 12aa and 12ba. This also applies to other embodiments.

The manufacturing method according to this embodiment has the following features.

(1) In the first embodiment, in plan view, the N layer 27a and the N⁺ layer 30a, which are N-type impurity regions, are formed at the area of the second mask material layer 12aa, and the N layer 27b and the N⁺ layer 30b, which are N-type impurity regions, are formed at the area of the second mask material layer 12ab. In this embodiment, the N layer 27aa, which is an N-type impurity region, is formed at the area of the second mask material layer 12aa, and the N layer 27ba, which is an N-type impurity region, is formed at the area of the second mask material layer 12ab. Since the N layers 27aa and 27ba are formed at the area of the second mask material layer 12aa, the N layers 27aa and 27ba in this embodiment are formed in a self-aligned manner with respect to the P-layer semiconductor pillar 15. Regarding the N⁺ layers 30aa and 30ba, as illustrated in FIGS. 4CA to 4CC, the N⁺ layers 30aa and 30ba containing a donor impurity are formed in contact with the side surface of the P-layer semiconductor pillar 15 exposed in the line X-X′ direction using selective epitaxial crystal growth; thus, the N⁺ layers 30aa and 30ba are formed in a self-aligned manner with respect to the P-layer semiconductor pillar 15. As a result of this, also in this embodiment, the P-layer semiconductor pillar 15, the first gate insulating layer 21, the first gate conductor layer 22, the second gate insulating layer 34, the second gate conductor layer 35a, the N layers 18a, 27aa, and 27ba, and the N⁺ layers 30aa and 30ba are formed in a self-aligned manner.
(2) In this embodiment, the N⁺ layers 30aa and 30ba are formed outside the P-layer semiconductor pillar 15 in plan view. This enables the width of the P-layer semiconductor pillar 15 in the line X-X′ direction to be smaller. Furthermore, connecting the N⁺ layers 30aa and 30ba to N⁺ layers of adjacent memory cells enables the pitch between memory cells to be smaller. This can provide a memory cell with a higher degree of integration.

### Other Embodiments

In the description of the embodiments, the vertical sectional shape of the P-layer semiconductor pillar 15 has been described as rectangular, but it may be trapezoidal or barrel-shaped. The horizontal section of the P-layer semiconductor pillar 15 may have a square shape, a rectangular shape, or a shape with rounded corners.

In the description of the embodiments, the N layer 18 is illustrated as connecting to adjacent memory cells, but the N layer 18 may be present only in the bottom portion of the P-layer semiconductor pillar 15. In this case, the N layer is not connected to the control line CL, but normal memory operation can be performed.

When the N layer 18a described in the embodiments connects to adjacent memory cells and connects to the control line CL, an N⁺ layer or a conductor layer containing a large amount of donor impurity may be provided on a part or the entire surface of the N layer 18a in the outer peripheral portion of the P-layer semiconductor pillar 15 in plan view.

In the memory cell illustrated in FIGS. 1MA to 1MC, the N⁺ layer 30a connecting to the source line SL may be shared by adjacent cells. The N⁺ layer 30b connecting to the bit line BL may be shared by adjacent cells. This provides a memory region with a higher degree of integration. This also applies to other embodiments.

In the embodiments, the first gate conductor layer 22 may be divided into two in the horizontal direction or the vertical direction so as to be driven synchronously or asynchronously. This also allows normal memory operation. For example, the first gate conductor layer 22 may be divided in the horizontal direction such that each division is connected to each one of the divided first gate conductor layers of memory cells on both sides.

The P layer 10 in the embodiments may be a silicon-on-insulator (SOI) substrate or a substrate having, for example, a well structure. A MOS transistor circuit formed on another substrate may be provided on the upper side, the lower side, or both sides of the memory cell.

In the first embodiment, a memory element in which holes serve as write carriers has been described using the N layers 18a, 27a, and 27b, the N⁺ layers 30a and 30b, and the P-layer semiconductor pillar 15. Alternatively, the N layers 18a, 27a, and 27b and the N⁺ layers 30a and 30b may be replaced with P-type impurity layers to form a memory element in which electrons serve as write carriers. Impurity layers of both types may be formed on one and the same substrate. This also applies to other Examples.

In FIGS. 1MA to 1MC, the metal wiring layers 37 and 41 are formed in contact with the upper surfaces of the N⁺ layers 30a and 30b, respectively. Alternatively, the metal wiring layers 37 and 41 may be formed in contact with the side surfaces of the N⁺ layers 30a and 30b, respectively. This also applies to other Examples.

Various embodiments and modifications of the present invention can be made without departing from the broad spirit and scope of the present invention. The foregoing embodiments are illustrative of examples of the present invention and are not intended to limit the scope of the present invention. The foregoing examples and modifications can be combined in any manner. Furthermore, the foregoing embodiments fall within the scope of the technical idea of the present invention even if some elements are excluded from those embodiments as needed.

The use of a semiconductor device including a memory element and a method for manufacturing the semiconductor device according to the present invention can provide a high-performance and low-cost semiconductor device.

What is claimed is:

1. A method for manufacturing a semiconductor device including a memory element, the method comprising:
a step of forming, on a semiconductor layer, a first band-shaped material layer extending in a first direction in plan view;
a step of forming, on both sides of the first band-shaped material layer, a second band-shaped material layer having an equal width;
a step of forming, on the semiconductor layer, a third band-shaped material layer covering the first and second band-shaped material layers and extending in a second direction perpendicular to the first direction;
a step of etching the first and second band-shaped material layers using the third band-shaped material layer as a mask to form a first mask material layer that is a part of the first band-shaped material layer and, on both sides of the first mask material layer, a second mask material layer that is a part of the second band-shaped material layer;
a step of etching the semiconductor layer using the first and second mask material layers as masks to form a semiconductor pillar;
a step of forming a first impurity region in a bottom portion of the semiconductor pillar;
a step of forming a first gate insulating layer in contact with a side surface of the semiconductor pillar;
a step of forming one or two first gate conductor layers in contact with a side surface of the first gate insulating layer;
a step of forming a second impurity region and a third impurity region in top portions of the semiconductor pillar at areas of the second mask material layer on the both sides of the first mask material layer in plan view;
a step of removing the first mask material layer to form a first hole; and
a step of forming a second gate insulating layer in contact with an inner side surface of the first hole and a second gate conductor layer in contact with the second gate insulating layer.

2. The method for manufacturing a semiconductor device including a memory element according to claim 1, the method comprising:
a step of removing the second mask material layer while leaving the first mask material layer;
a step of forming a first low-concentration impurity region in top portions of the semiconductor pillar on the both sides of the first mask material layer in plan view;
a step of forming, on the semiconductor pillar, a third mask material layer having an equal width on side surfaces of the first mask material layer in the second direction; and
a step of forming, in top portions of the semiconductor pillar on both sides of the third mask material layer, a first high-concentration impurity region containing more impurities than the first low-concentration impurity region,
wherein the first low-concentration impurity region and the first high-concentration impurity region form the second impurity region and the third impurity region.

3. The method for manufacturing a semiconductor device including a memory element according to claim 1,
wherein after the second impurity region and the third impurity region are formed using the first mask material layer as a mask, the first mask material layer is removed, and then the second gate insulating layer and the second gate conductor layer are formed.

4. The method for manufacturing a semiconductor device including a memory element according to claim 1,
wherein after the first mask material layer is removed and the second gate insulating layer and the second gate conductor layer are formed on the inner side surface of the first hole, the second mask material layer is removed, and then the second impurity region and the third impurity region are formed.

5. The method for manufacturing a semiconductor device including a memory element according to claim 1, the method further comprising:
a step of forming the second mask material layer as a fourth mask material layer formed on the both sides of the first mask material layer and having an equal width and a fifth mask material layer formed on both sides of the fourth mask material layer and having an equal width;
a step of removing the fifth mask material layer;
a step of forming a second high-concentration impurity region in top portions of the semiconductor pillar at areas where the fifth mask material layer has once been present in plan view;
a step of removing the fourth mask material layer; and
a step of forming a second low-concentration impurity region in top portions of the semiconductor pillar at areas where the fourth mask material layer has once been present in plan view.

6. The method for manufacturing a semiconductor device including a memory element according to claim 1, the method further comprising
a step of forming the second impurity region and the third impurity region on the both sides of the first mask material layer such that the second impurity region and the third impurity region are adjacent to the first mask material layer and include an upper surface portion of the semiconductor pillar in plan view.

7. The method for manufacturing a semiconductor device including a memory element according to claim 1, the method further comprising:
a step of removing the first mask material layer;
a step of forming a second hole by etching a top portion of the semiconductor pillar at an area of the removed first mask material layer using the second mask material layer as an etching mask such that a bottom of the hole in a vertical direction is located higher than an upper surface of the first gate conductor layer;
a step of forming the second gate insulating layer and the second gate conductor layer in contact with an inner side surface of the second hole;
a step of removing the second mask material layer; and
a step of forming the second impurity region and the third impurity region in top portions of the semiconductor pillar located above a bottom portion of the second hole.

8. The method for manufacturing a semiconductor device including a memory element according to claim 7,
wherein after the second gate insulating layer and the second gate conductor layer are formed, the second mask material layer is removed, and then the second impurity region and the third impurity region are formed.

9. The method for manufacturing a semiconductor device including a memory element according to claim 7,
wherein after the second impurity region and the third impurity region are formed using the first mask material layer as a mask, the second gate insulating layer and the second gate conductor layer are formed in contact with the inner side surface of the second hole formed by removing the first mask material layer.

10. The method for manufacturing a semiconductor device including a memory element according to claim 7,
wherein in the vertical direction, an upper surface of the second gate conductor layer is located near bottom portions of the second impurity region and the third impurity region.

11. The method for manufacturing a semiconductor device including a memory element according to claim 1, the method comprising:
a step of removing the second mask material layer while leaving the first mask material layer;
a step of forming a second low-concentration impurity region in top portions of the semiconductor pillar at areas of the second mask material layer in plan view; and
a step of forming a second high-concentration impurity region in contact with an outer side of the second low-concentration impurity region in the second direction.

12. The method for manufacturing a semiconductor device including a memory element according to claim 11,
wherein the second high-concentration impurity region is formed by selective epitaxial crystal growth.

13. The method for manufacturing a semiconductor device including a memory element according to claim 11,
wherein the second high-concentration impurity region is connected to an adjacent high-concentration impurity region of an adjacent memory cell.

14. The method for manufacturing a semiconductor device including a memory element according to claim 1, the method further comprising:
a step of forming, after forming the semiconductor pillar, an impurity layer having a conductivity type opposite to that of the semiconductor pillar in an upper layer of the semiconductor layer at an outer peripheral portion of the semiconductor pillar; and
a step of thermally oxidizing the upper layer of the semiconductor layer at the outer peripheral portion of the semiconductor pillar to form a thermally oxidized layer in the outer peripheral portion and an inner peripheral portion of the semiconductor pillar,
wherein the impurity layer having the opposite conductivity type spreads, upon heat treatment, throughout the bottom portion of the semiconductor pillar to form the first impurity region.

15. The method for manufacturing a semiconductor device including a memory element according to claim 1, the method comprising
a step of dividing the first gate conductor layer at a central portion between the second impurity region and the third impurity region in a direction in which the second impurity region and the third impurity region connect to each other in plan view to form a fourth gate conductor layer and a fifth gate conductor layer.

16. A semiconductor device including a memory element, comprising:
a semiconductor pillar extending in a vertical direction on a substrate;
a first impurity region connecting to a bottom portion of the semiconductor pillar;
a first gate insulating layer in contact with a lower side surface of the semiconductor pillar;
one or two first gate conductor layers in contact with a side surface of the first gate insulating layer;
a second impurity region and a third impurity region that are disposed above an upper surface of the first gate conductor layer in the vertical direction and disposed at both ends of a top portion of the semiconductor pillar in a first direction in plan view and that have an equal width;
a second gate insulating layer disposed on the top portion of the semiconductor pillar between the second impurity region and the third impurity region; and
a second gate conductor layer in contact with the second gate insulating layer,
wherein a top section of a portion of the semiconductor pillar that is in contact with the first gate insulating layer and a bottom section of a portion of the semiconductor pillar that is in contact with the top section and includes the second impurity region and the third impurity region overlap each other with a substantially equal shape in plan view.

17. The semiconductor device including a memory element according to claim 16,
wherein the second impurity region comprises a first low-concentration impurity region disposed outside the second gate conductor layer in plan view and having a low impurity concentration and a first high-concentration impurity region disposed outside the first low-concentration impurity region in plan view, and
the third impurity region comprises a second low-concentration impurity region disposed outside the second gate conductor layer in plan view and equal in width and impurity concentration to the first low-concentration impurity region and a second high-concentration impurity region disposed outside the second low-concentration impurity region in plan view and equal in width and impurity concentration to the first high-concentration impurity region.

18. The semiconductor device including a memory element according to claim 16,
wherein the second impurity region comprises a third low-concentration impurity region having a low impurity concentration,
the third impurity region comprises a fourth low-concentration impurity region having an impurity concentration equal to that of the third low-concentration impurity region, and
in the first direction, a third high-concentration impurity region is disposed in contact with an outer side of the third low-concentration impurity region, and a fourth high-concentration impurity region having an impurity concentration equal to that of the third high-concentration impurity region is disposed in contact with an outer side of the fourth low-concentration impurity region.

19. The semiconductor device including a memory element according to claim 18,
wherein the third and fourth high-concentration impurity regions are formed by selective epitaxial crystal growth.

20. The semiconductor device including a memory element according to claim 16,
wherein the two separate first gate conductor layers are configured such that a fixed voltage or zero voltage is applied to one of the two separate first gate conductor layers.

21. The semiconductor device including a memory element according to claim 20,
wherein one of the two separate first gate conductor layers to which a fixed voltage or zero voltage is applied is adjacent to the second impurity region connected to a bit line or the third impurity region in plan view.

22. The semiconductor device including a memory element according to claim 16,
wherein an upper surface of the semiconductor pillar between the second impurity region and the third impurity region is located below bottom portions of the second impurity region and the third impurity region.

23. The semiconductor device including a memory element according to claim 22,
wherein a wiring metal layer is disposed in contact with an upper portion of the second gate conductor layer, and
an upper end of the wiring metal layer is located below or near lower ends of the second and third impurity regions in the vertical direction.

24. The semiconductor device including a memory element according to claim 16,
wherein the first low-concentration impurity region surrounds an entire side surface of the first high-concentration impurity region, and the second low-concentration impurity region surrounds an entire side surface of the second high-concentration impurity region.

25. The semiconductor device including a memory element according to claim 17,
wherein a thermally oxidized layer is disposed between the substrate and the first gate conductor layer and disposed in an outer peripheral portion and an inner peripheral portion of the bottom portion of the semiconductor pillar.

26. The semiconductor device including a memory element according to claim 16,
wherein the second impurity region and the third impurity region are disposed so as to be adjacent to the second gate conductor layer and to include an upper surface portion of the semiconductor pillar in plan view.
